(19) United States
(12) Patent Application Publication
(10) Pub. No.: US 2015/0228786 A1
(43) Pub. Date: Aug. 13, 2015

(54) Semiconductor Device

(71) Applicant: Samsung Electronics Co., Ltd., Suwon-si (KR)

(72) Inventors: Wook-Yeol Yi, Hwaseong-si (KR); Ki-Hong Nam, Seongnam-si (KR); Dong-Chan Kim, Anyang-si (KR); Hee-Don Hwang, Yongin-si (KR); Young-Min Kim, Hwaseong-si (KR); Duk-Young Jang, Hwaseong-si (KR)

(21) Appl. No.: 14/542,867

(22) Filed: Nov. 17, 2014

(30) Foreign Application Priority Data
Feb. 12, 2014 (KR) 10-2014-0016099

(51) Int. Cl. H01L 29/78; H01L 29/423

(52) U.S. Cl. CPC H01L 29/7843; H01L 29/7827; H01L 29/4236

(57) ABSTRACT

A semiconductor device includes a semiconductor substrate having an active region. A gate trench is disposed to cross the active region. First and second source/drain regions are disposed in the active region at both sides of the gate trench. A gate electrode is disposed in the gate trench. A gate dielectric layer is disposed between the gate electrode and the active region. A stress pattern is disposed on the gate electrode and in the gate trench. The stress pattern has a lower residual stress than silicon nitride.

### CROSS-REFERENCE TO RELATED APPLICATION

This application claims priority under 35 U.S.C. §119 to Korean Patent Application No. 10-2014-0016099 filed on Feb. 12, 2014, the disclosure of which is hereby incorporated by reference in its entirety.

### BACKGROUND

1. Technical Field

Embodiments of the inventive concept relate to semiconductor devices having a transistor, methods of forming the semiconductor devices, and semiconductor modules and an electronic system adopting the same.

2. Description of Related Art

According to a high integration trend of a semiconductor device, a 3-dimensional transistor has been used as a switching device. In a dynamic random access memory (DRAM), a 3-dimensional transistor having a gate structure buried in a substrate has been proposed. In addition, various proposals and studies are being executed in order to improve and stabilize an operation and reliability of a buried gate structure.

### SUMMARY

In accordance with an embodiment of the inventive concept, a semiconductor device includes a semiconductor substrate having an active region. A gate trench is disposed to cross the active region. First and second source/drain regions are disposed in the active region at both sides of the gate trench. A gate electrode is disposed in the gate trench. A gate dielectric layer is disposed between the gate electrode and the active region. A stress pattern is disposed on the gate electrode and in the gate trench. The stress pattern has a lower residual stress than silicon nitride.

In an embodiment, the material of the stress pattern may have a lower permittivity than the silicon nitride.

In an embodiment, the material of the stress pattern may be a material of which residual stress and permittivity are lowered compared to those of silicon nitride by adding boron into the silicon nitride.

In an embodiment, the material of the stress pattern may be a material of which residual stress and permittivity are lowered compared to those of the silicon nitride by adding carbon or oxygen together with boron into the silicon nitride.

In an embodiment, an insulating pattern disposed on the gate electrode and in the gate trench may be further included, wherein the insulating pattern may be formed of a different material from the stress pattern.

The insulating pattern may be formed of a material having a higher etch resistance than the stress pattern.

The insulating pattern may be disposed on the stress pattern.

The stress pattern may be interposed between the first and second source/drain regions and the insulating pattern.

The stress pattern may cover side and bottom surfaces of the insulating pattern.

In an embodiment, the active region may have p-type conductivity, and the first and second source/drain regions may have n-type conductivities.

In an embodiment, the stress pattern may face the first and second source/drain regions, and be spaced apart from the first and second source/drain regions.

In an embodiment, the gate dielectric layer may be interposed between the gate electrode and the active region, and between the stress pattern and the active region.

In accordance with an embodiment of the inventive concept, a semiconductor device includes a trench isolation layer disposed in a semiconductor substrate to define an active region. A gate trench is disposed to cross the active region and extend into the trench isolation layer. A gate electrode is disposed in the gate trench. A stress pattern is disposed in the gate trench and on the gate electrode. The stress pattern may be formed of a material having a smaller residual stress value than silicon nitride.

In an embodiment, the trench isolation layer includes a first isolation layer and a second isolation layer disposed on the first isolation layer, and the stress pattern may have a smaller residual stress value than the second isolation layer.

In another embodiment, the stress pattern may be in direct contact with an upper surface of the gate electrode, and may face the first and second source/drain regions.

It is noted that aspects of the invention described with respect to one embodiment, may be incorporated in a different embodiment although not specifically described relative thereto. That is, all embodiments and/or features of any embodiment can be combined in any way and/or combination. These and other objects and/or aspects of the present invention are explained in detail in the specification set forth below.

### BRIEF DESCRIPTION OF THE DRAWINGS

The foregoing and other features and advantages of the inventive concepts will be apparent from the more particular description of embodiments of the inventive concepts, as illustrated in the accompanying drawings in which like reference characters refer to the same parts throughout the different views. The drawings are not necessarily to scale, emphasis instead being placed upon illustrating the principles of the inventive concepts. In the drawings:

FIG. 1 is a plan view showing semiconductor devices in accordance with embodiments of the inventive concept;

FIGS. 2A and 2B are cross-sectional views showing a semiconductor device in accordance with an embodiment of the inventive concept;

FIGS. 3A and 3B are cross-sectional views showing a semiconductor device in accordance with an embodiment of the inventive concept;

FIGS. 4A and 4B are cross-sectional views showing a semiconductor device in accordance with an embodiment of the inventive concept;

FIGS. 5A and 5B are cross-sectional views showing a semiconductor device in accordance with an embodiment of the inventive concept;

FIGS. 6A, 6B, 7A, 7B, 8A, 8B, 9A, and 9B are cross-sectional views showing a method of forming a semiconductor device in accordance with an embodiment of the inventive concept;

FIGS. 10A, 10B, 11A, and 11B are cross-sectional views showing a method of forming a semiconductor device in accordance with an embodiment of the inventive concept;

FIGS. 12A, 12B, 13A, and 13B are cross-sectional views showing a method of forming a semiconductor device in accordance with an embodiment of the inventive concept;

FIGS. 14A, 14B, 15A, and 15B are cross-sectional views showing a method of forming a semiconductor device in accordance with an embodiment of the inventive concept;

FIG. 16 is a view showing the residual stress characteristics;

FIG. 17 is a view showing the Ion characteristics of a transistor;

FIG. 18 is a view showing the effective mobility characteristics of a transistor;

FIG. 19 is a schematic view illustrating a semiconductor module including a semiconductor device in accordance with an embodiment of the inventive concept;

FIG. 20 is a schematic view illustrating a semiconductor module including a semiconductor device in accordance with an embodiment of the inventive concept;

FIG. 21 is a conceptual block diagram illustrating an electronic system including a semiconductor device in accordance with an embodiment of the inventive concept;

FIG. 22 is a schematic block diagram illustrating another electronic system including a semiconductor device in accordance with an embodiment of the inventive concept; and

FIG. 23 is a schematic view illustrating a mobile wireless phone including a semiconductor device in accordance with an embodiment of the inventive concept.

### DETAILED DESCRIPTION OF THE EMBODIMENTS

The inventive concept may, however, be embodied in various different forms, and should be construed as limited, not by the embodiments set forth herein, but only by the accompanying claims. Rather, these embodiments are provided so that this disclosure is thorough and complete and fully conveys the inventive concept to those skilled in the art. In the drawings, the sizes and relative sizes of layers and regions may be exaggerated for clarity. The same reference symbols denote the same components throughout the specification.

Embodiments are described herein with reference to cross-sectional views, plan views, and/or block diagrams that are schematic illustrations of idealized embodiments. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. Therefore, regions illustrated in the drawings are schematic in nature, and their shapes are not intended to limit the inventive concept but only to illustrate characteristic forms of regions of devices.

The thicknesses of layers and regions in the drawings may be exaggerated for the sake of clarity. Further, it will be understood that when a layer is referred to as being “on” another layer or a substrate, the layer may be formed directly on the other layer or the substrate, or there may be an intervening layer therebetween. The same reference numerals indicate the same components throughout the specification.

Terms such as “top,” “bottom,” “upper,” “lower,” “above,” “below,” and the like are used herein to describe the relative positions of elements or features. It will be understood that such descriptions are intended to encompass different orientations in use or operation in addition to orientations depicted in the drawings. For example, when an upper part of a drawing is referred to as a “top” and a lower part of a drawing as a “bottom” for the sake of convenience, in practice, the “top” may also be called a “bottom” and the “bottom” a “top” without departing from the teachings of the inventive concept.

Furthermore, throughout this disclosure, directional terms such as “upper,” “intermediate,” “lower,” and the like may be used herein to describe the relationship of one element or feature with another, and the inventive concept should not be limited by these terms. Accordingly, these terms such as “upper,” “intermediate,” “lower,” and the like may be replaced by other terms such as “first,” “second,” “third,” and the like to describe the elements and features.

It will be understood that, although the terms “first,” “second,” etc. may be used herein to describe various elements, these elements should not be limited by these terms. These terms are only used to distinguish one element from another. Thus, a first element could be termed a second element without departing from the teachings of the present inventive concept.

The terminology used herein to describe embodiments of the invention is not intended to limit the scope of the invention.

As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

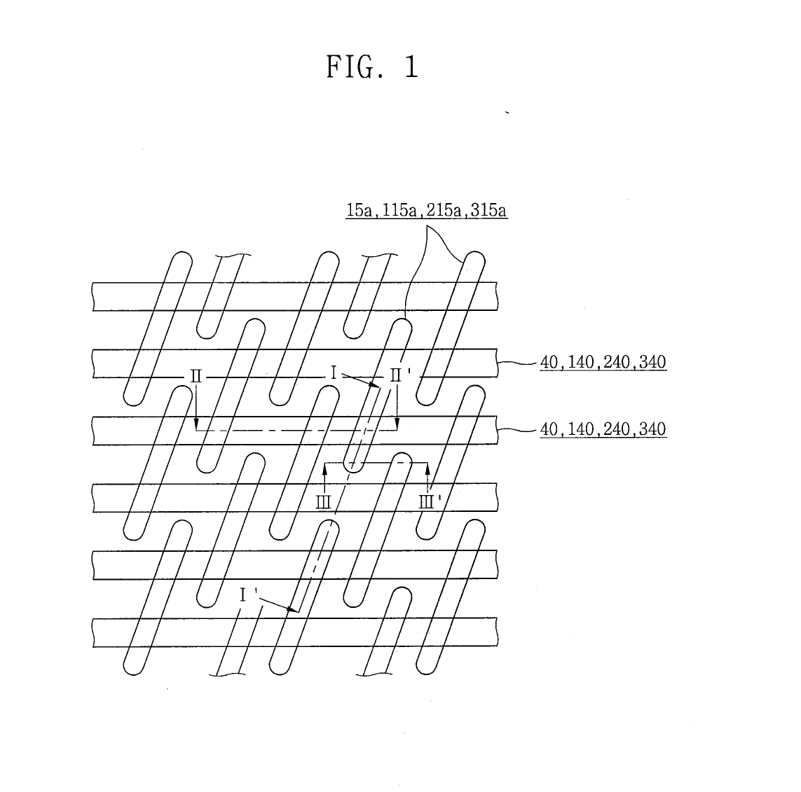

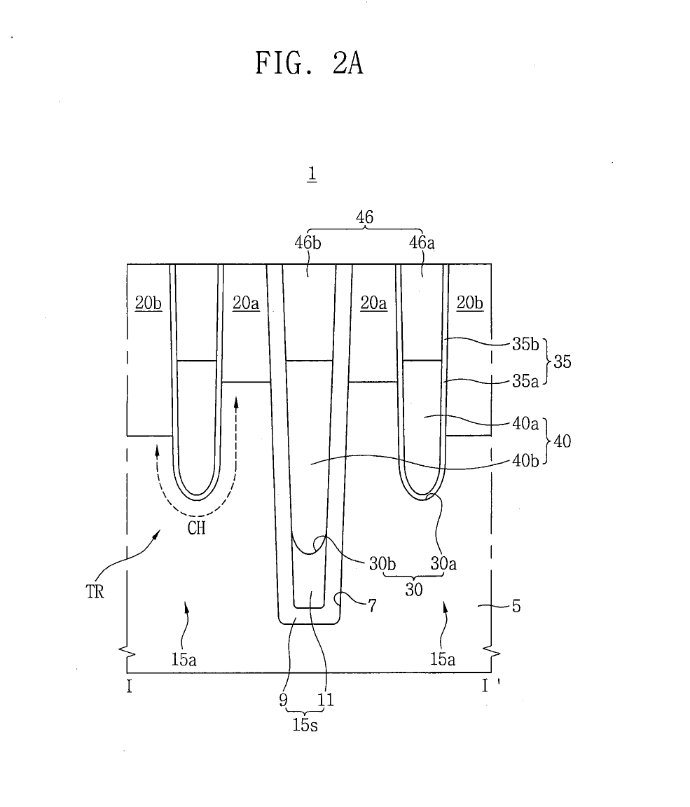

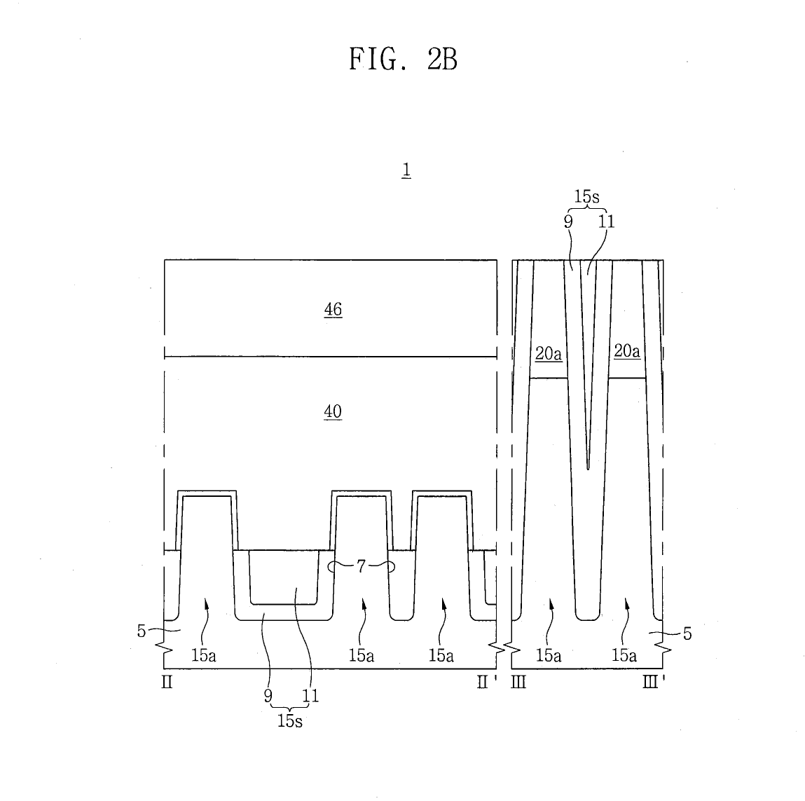

FIG. 1 is a plan view showing semiconductor devices in accordance with some embodiments of the inventive concept. FIGS. 2A and 2B are cross-sectional views showing a semiconductor device in accordance with an embodiment of the inventive concept. FIG. 2A is a cross-sectional view showing an area taken along line I-I′ of FIG. 1, and FIG. 2B is a cross-sectional view showing an area taken along line II-IF of FIG. 1 and an area taken along line III-III′ of FIG. 1.

Referring to FIGS. 1, 2A, and 2B, a semiconductor device 1 in accordance with an embodiment of the inventive concept may include a trench isolation layer 15s disposed in a semiconductor substrate 5 to define an active region 15a. Further, the semiconductor device 1 may include a transistor TR and a stress pattern 46.

The semiconductor substrate 5 may be a substrate formed of a semiconductor material such as silicon, etc. The trench isolation layer 15s may include a first isolation layer 9 and a second isolation layer 11. The first isolation layer 9 may be disposed on an inner wall of an isolation trench 7 located in the semiconductor substrate 5. The second isolation layer 11 may be disposed on the first isolation layer 9. The second isolation layer 11 may be disposed on the first isolation layer 9, and may fill the isolation trench 7. The first isolation layer 9 may be formed of a silicon oxide layer, and the second isolation layer 11 may be formed of a silicon nitride layer.

The transistor TR may be a 3-dimensional transistor. The transistor TR may include a gate electrode 40, a gate dielectric layer 35, a first source/drain region 20a, and a second source/drain region 20b.

The gate electrode 40 may be disposed in a gate trench 30 to cross the active region 15a and extend onto the trench isolation layer 15s. The gate trench 30 may have a first portion 30a located in the active region 15a, and a second portion 30b located in the trench isolation layer 15s. The second portion 30b of the gate trench 30 may have a bottom surface located at a lower level than the first portion 30a of the gate trench 30. The gate electrode 40 may partially fill the gate trench 30. The gate electrode 40 may be disposed at a lower level than an upper surface of the active region 15a and an upper surface of the trench isolation layer 15s.

The gate electrode 40 may have a first portion 40a located in the active region 15a, and a second portion 40b located in the trench isolation layer 15s. The second portion 40b of the gate electrode 40 may have a bottom surface located at a lower level than the first portion 40a of the gate electrode 40. Therefore, the second portion 40b of the gate electrode 40 may face a side surface of the active region 15a located under the first portion 40a of the gate electrode 40. The gate electrode 40 may be formed of a conductive material such as tungsten, titanium nitride, tantalum nitride, or tungsten nitride.

The first and second source/drain regions 20a and 20b may be disposed in the active region 15a located at both sides of the gate trench 30. The first and second source/drain regions 20a and 20b may be spaced apart from each other by interposing the gate trench 30.

In an embodiment, when the active region 15a has p-type conductivity, the first and second source/drain regions 20a and 20b may have n-type conductivities. Therefore, the transistor TR may be a negative-channel metal-oxide-semiconductor (NMOS) transistor.

The first and second source/drain regions 20a and 20b may be an asymmetric structure. For example, a junction depth of the second source/drain region 20b may be deeper than a junction depth of the first source/drain region 20a. Some portion of the gate electrode 40 may face some portion of the first source/drain region 20a and/or some portion of the second source/drain region 20b. A size of a portion in which the gate electrode 40 and the second source/drain region 20b face each other may be greater than a size of a portion in which the gate electrode 40 and the first source/drain region 20a face each other.

A channel area CH of the transistor TR may be defined in the active region 15a. The channel area CH may be defined in an active region between the first source/drain region 20a and the second source/drain region 20b.

The stress pattern 46 may be disposed on the gate electrode 40. The stress pattern 46 is disposed on an upper portion of the gate electrode 40, and may be disposed in the gate trench 30. The stress pattern 46 may be in direct contact with an upper surface of the gate electrode 40. The stress pattern 46 may face the first and second source/drain regions 20a and 20b, and may be spaced apart from the first and second source/drain regions 20a and 20b. The stress pattern 46 may be spaced apart from the active region 15a. The first and second source/drain regions 20a and 20b may be disposed in the active region 15a located at both sides of the stress pattern 46.

The stress pattern 46 may have a first portion 46a and a second portion 46b. The first portion 46a of the stress pattern 46 may be disposed on an upper portion of the first portion 40a of the gate electrode 40 located in the active region 15a, and the second portion 46b of the stress pattern 46 may be disposed on an upper portion of the second portion 40b of the gate electrode 40 located in the trench isolation layer 15s.

The stress pattern 46 may be formed of a material having a lower residual stress than the second isolation layer 11 of the trench isolation layer 15s. For example, the second isolation layer 11 may be formed of silicon nitride, and the stress pattern 46 may have a lower residual stress than the second isolation layer 11 formed of silicon nitride. The stress pattern 46 may have a smaller residual stress value than the second isolation layer 11 formed of silicon nitride.

In the embodiments, the expression, “a lower residual stress than ˜” may refer to “a smaller value of residual stress than ˜.”

In an embodiment, the stress pattern 46 may be formed of a material having a lower residual stress than silicon nitride. For example, the stress pattern 46 may be formed to include at least one of SiBN, SiBCN, SiOCN, SiOBN, SiON, BN, or SiCN.

In an embodiment, the stress pattern 46 may be formed of a material having a lower residual stress than silicon nitride, and having lower permittivity than the silicon nitride. For example, the stress pattern 46 may be formed to include at least one of SiBN, SiOCN, SiOBN, SiON, or BN.

In an embodiment, the stress pattern 46 may be formed of a material having lowered residual stress and permittivity than silicon nitride by adding boron (B) as impurities into silicon nitride.

In an embodiment, the stress pattern 46 may be formed of a material having lowered residual stress and permittivity than silicon nitride by adding oxygen (O) or carbon (C) together with boron (B) as impurities into silicon nitride.

The gate dielectric layer 35 may have a first portion 35a interposed between the gate electrode 40 and the active region 15a, and a second portion 35b interposed between the stress pattern 46 and the active region 15a. The second portion 35b of the gate dielectric layer 35 may prevent that the stress pattern 46 and the active region 15a are in direct contact with each other by interposing between the stress pattern 46 and the active region 15a. The second portion 35b of the gate dielectric layer 35 may prevent performance deterioration of the transistor TR caused by a direct contact between the stress pattern 46 and the active region 15a. The gate dielectric layer 35 may be formed of a thermal oxide layer. For example, the gate dielectric layer 35 may be formed of silicon oxide using a thermal oxidation process.

The stress pattern 46 may improve a performance of the transistor TR by improving the resistance characteristics of the transistor TR. For example, the stress pattern 46 may reduce a channel resistance of the transistor TR.

The stress pattern 46 may improve a performance of the transistor TR by increasing effective mobility of the transistor TR.

The stress pattern 46 may improve a performance of the transistor TR by increasing Ion (on-current) of the transistor TR.

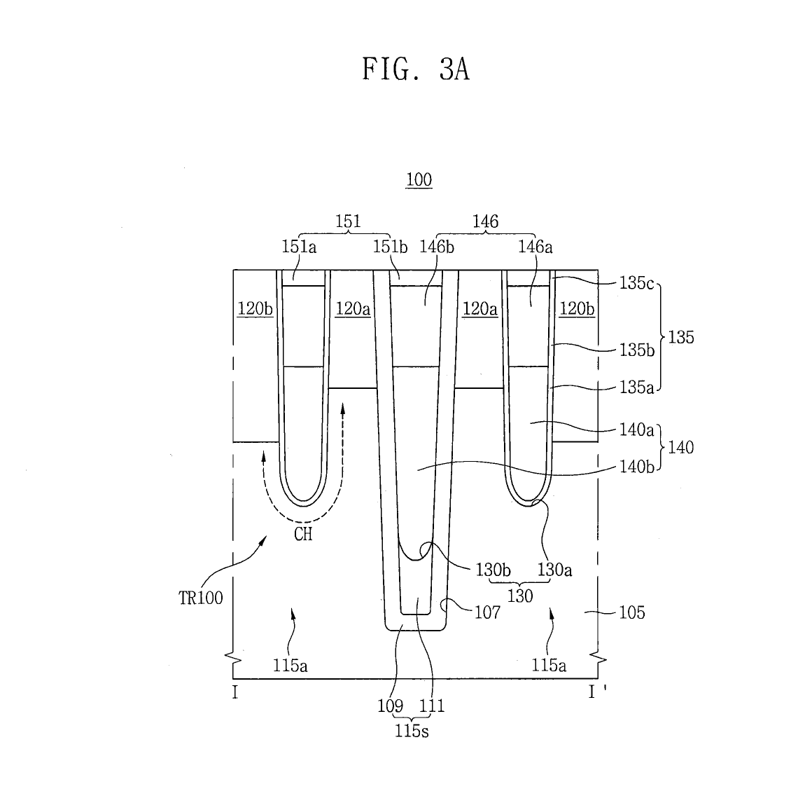

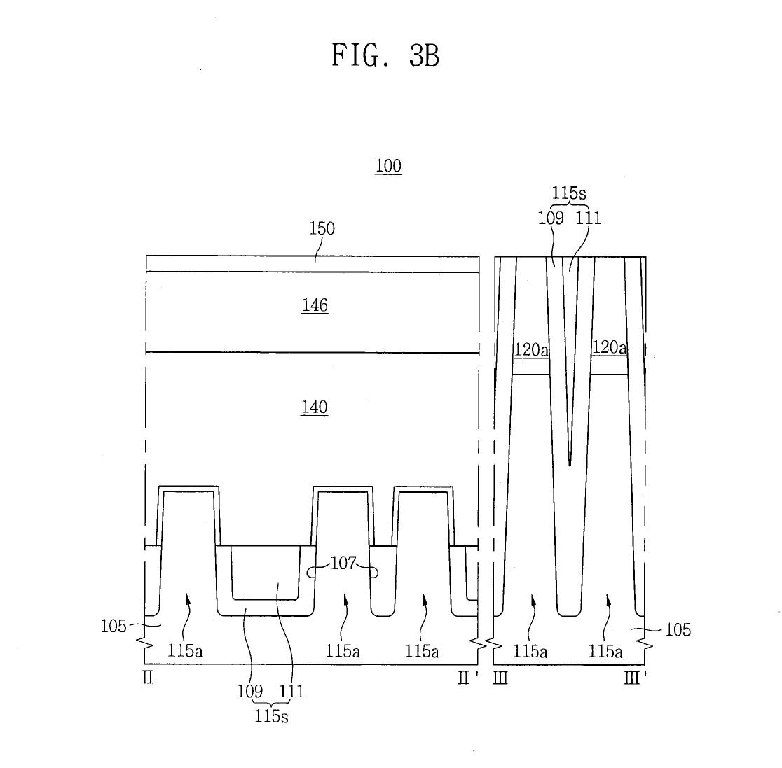

Hereinafter, a semiconductor device 100 in accordance with another embodiment of the inventive concept will be described with reference to FIGS. 3A and 3B with FIG. 1.

Referring to FIGS. 1, 3A, and 3B, a semiconductor device 100 in accordance with another embodiment of the inventive concept may include a trench isolation layer 115s disposed in a semiconductor substrate 105 to define an active region 115a. Further, the semiconductor device 100 may include a transistor TR100, a stress pattern 146, and an insulating pattern 151.

The trench isolation layer 115s may include a first isolation layer 109 and a second isolation layer 111 like the trench isolation layer 15s of FIGS. 2A and 2B, the first isolation layer 109 may be disposed on an inner wall of an isolation trench 107 located in the semiconductor substrate 105, and the second isolation layer 111 may be disposed on the first isolation layer 109.

The transistor TR100 may be a 3-dimensional transistor. The transistor TR100 may include a gate electrode 140, a gate dielectric layer 135, a first source/drain region 120a, and a second source/drain region 120b. A channel area CH of the transistor TR100 may be defined in the active region 115a which is located between the first and second source/drain regions 120a and 120b, and located in a lower portion of the gate electrode 140.

The gate electrode 140 may be actually the same as the gate electrode 40 of FIGS. 2A and 2B, the gate dielectric layer 135 may be actually the same as the gate dielectric layer 35 of FIGS. 2A and 2B, and the first and second source/drain regions 120a and 120b may be actually the same as the first and second source/drain regions 20a and 20b of FIGS. 2A and 2B. For example, the gate electrode 140 may be disposed in a gate trench 130 to cross the active region 115a and extend onto the trench isolation layer 115s, and the first and second source/drain regions 120a and 120b may be disposed in the active region 115a located at both sides of the gate trench 130. The gate trench 130 may include a first portion 130a to cross the active region 115a, and a second portion 130b located in the trench isolation layer 115s.

The stress pattern 146 may be disposed on the gate electrode 140. The stress pattern 146 may be in direct contact with an upper surface of the gate electrode 140.

The stress pattern 146 may be disposed in the gate trench 130 of an upper portion of the gate electrode 140, and may be disposed at a lower level than an upper surface of the active region 115a. The stress pattern 146 may have a first portion 146a and a second portion 146b. The first portion 146a of the stress pattern 146 may be disposed on an upper portion of a first portion 140a of the gate electrode 140 located in the active region 115a, and the second portion 146b of the stress pattern 146 may be disposed on an upper portion of a second portion 140b of the gate electrode 140 located in the trench isolation layer 115s.

The stress pattern 146 may face the first source/drain region 120a and/or the second source/drain region 120b. The stress pattern 146 may be formed of the same material as the stress pattern 46 of FIGS. 2A and 2B. For example, the stress pattern 146 may be formed of a material having a smaller residual stress value than the second isolation layer 111, for example, silicon nitride.

The insulating pattern 151 may be disposed on the stress pattern 146, and may be disposed in an upper area of the gate trench 130.

The insulating pattern 151 may be formed of a different material from the stress pattern 146. The insulating pattern 151 may be formed of a material having an etch selectivity with respect to the stress pattern 146. The insulating pattern 151 may be formed of a material having a higher etch resistance than the stress pattern 146. For example, the stress pattern 146 may be formed of silicon nitride to which boron is added as impurities, and the insulating pattern 151 may be formed of silicon nitride to which boron is not added.

The insulating pattern 151 may have a first portion 151a and a second portion 151b. The first portion 151a of the insulating pattern 151 may cover the first portion 146a of the stress pattern 146, and the second portion 151b of the insulating pattern 151 may cover the second portion 146b of the stress pattern 146. The insulating pattern 151 may protect the stress pattern 146. For example, the insulating pattern 151, by preventing excessive over-etch of the stress pattern 146 from the following etching process, may prevent a performance degradation of the transistor TR100.

The gate dielectric layer 135 may include a first portion 135a interposed between the gate electrode 140 and the active region 115a, a second portion 135b interposed between the stress pattern 146 and the active region 115a, and a third portion 135c interposed between the insulating pattern 151 and the active region 115a. The second portion 135b of the gate dielectric layer 135 may prevent performance deterioration of the transistor TR100 caused by a direct contact between the stress pattern 146 and the active region 115a.

The stress pattern 146 may improve a performance of the transistor TR100 by improving the resistance characteristics of the transistor TR100. The stress pattern 146 may improve a performance of the transistor TR100 by increasing effective mobility of the transistor TR100. The stress pattern 146 may improve a performance of the transistor TR100 by increasing Ion (on-current) of the transistor TR100.

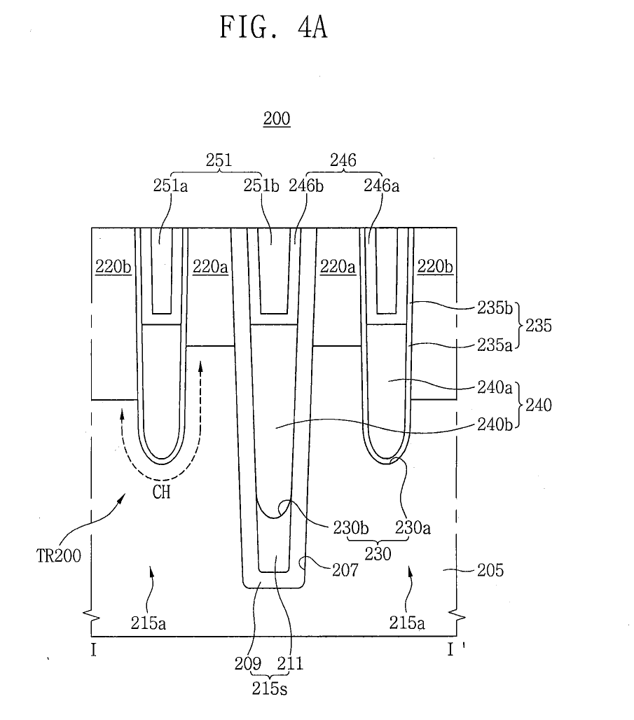

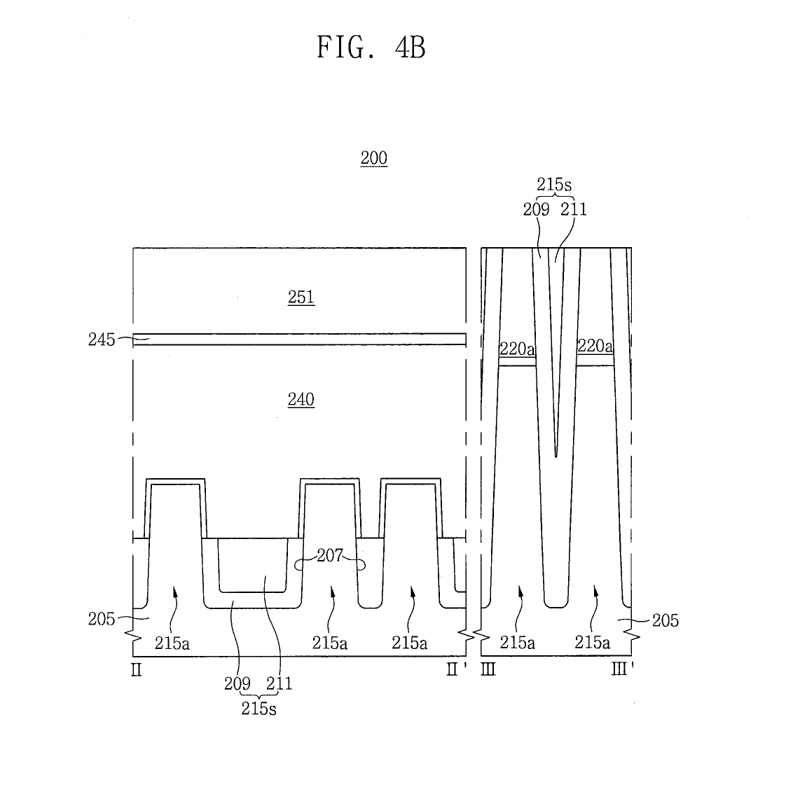

Hereinafter, a semiconductor device 200 in accordance with an embodiment of the inventive concept will be described with reference FIGS. 4A and 4B with FIG. 1.

Referring to FIGS. 1, 4A, and 4B, a semiconductor device 200 in accordance with an embodiment of the inventive concept may include a trench isolation layer 215s disposed in a semiconductor substrate 205 to define an active region 215a. Further, the semiconductor device 200 may include a transistor TR200, a stress pattern 246, and an insulating pattern 251.

The trench isolation layer 215s may include a first isolation layer 209 and a second isolation layer 211 like the trench isolation layer 15s of FIGS. 2A and 2B, the first isolation layer 209 may be disposed on an inner wall of an isolation trench 207 located in the semiconductor substrate 205, and the second isolation layer 211 may be disposed on the first isolation layer 209.

The transistor TR200 may be a 3-dimensional transistor. The transistor TR200 may include a gate electrode 240, a gate dielectric layer 235, a first source/drain region 220a, and a second source/drain region 220b. A channel area CH of the transistor TR200 may be defined in the active region 215a which is located between the first and second source/drain regions 220a and 220b, and located in a lower portion of the gate electrode 240.

The gate electrode 240 may be actually the same as the gate electrode 40 of FIGS. 2A and 2B, the gate dielectric layer 235 may be actually the same as the gate dielectric layer 35 of FIGS. 2A and 2B, and the first and second source/drain regions 220a and 220b may be actually the same as the first and second source/drain regions 20a and 20b of FIGS. 2A and 2B. For example, the gate electrode 240 may be disposed in a gate trench 230 to cross the active region 215a and extend onto the trench isolation layer 215s, the gate dielectric layer 235 may include a portion disposed between the gate electrode 240 and the active region 215a, and the first and second source/drain regions 220a and 220b may be disposed in the active region 215a located at both sides of the gate trench 230.

The stress pattern 246 and the insulating pattern 251 may be disposed on the gate electrode 240.

The stress pattern 246 may be disposed to cover side and bottom surfaces of the insulating pattern 251. The stress pattern 246 may have a first portion 246a and a second portion 246b. The first portion 246a of the stress pattern 246 may be disposed on an upper portion of a first portion 240a of the gate electrode 240 located in the active region 215a, and the second portion 246b of the stress pattern 246 may be disposed on an upper portion of a second portion 240b of the gate electrode 240 located in the trench isolation layer 215s. The stress pattern 246 may be interposed between the insulating pattern 251 and the gate electrode 240, and between the insulating pattern 251 and the active region 215a. The stress pattern 246 may have a portion to face the first and second source/drain regions 220a and 220b. The stress pattern 246 may be closer to the active region 215a than the insulating pattern 251. The stress pattern 246 may be closer to the first and second source/drain regions 220a and 220b than the insulating pattern 251. The stress pattern 246 may be formed of the same material as the stress pattern 46 of FIGS. 2A and 2B. For example, the stress pattern 246 may be formed of a material having a smaller residual stress value than the second isolation layer 211.

The insulating pattern 251 may be formed of the same material as the insulating pattern 151 of FIGS. 3A and 3B. The insulating pattern 251 may be formed of a different material from the stress pattern 246. The insulating pattern 251 may be formed of a material having an etch selectivity with respect to the stress pattern 246. The insulating pattern 251 may be formed of a material having a higher etch resistance than the stress pattern 246. For example, the stress pattern 246 may be formed of silicon nitride to which boron is added as impurities, and the insulating pattern 251 may be formed of silicon nitride to which boron is not added.

The gate dielectric layer 235 may include a first portion 235a interposed between the gate electrode 240 and the active region 215a, and a second portion 235b interposed between the stress pattern 246 and the active region 215a.

The stress pattern 246 may improve a performance of the transistor TR200 by improving the resistance characteristics of the transistor TR200. The stress pattern 246 may improve a performance of the transistor TR200 by increasing effective mobility of the transistor TR200. The stress pattern 246 may improve a performance of the transistor TR200 by increasing Ion (on-current) of the transistor TR200.

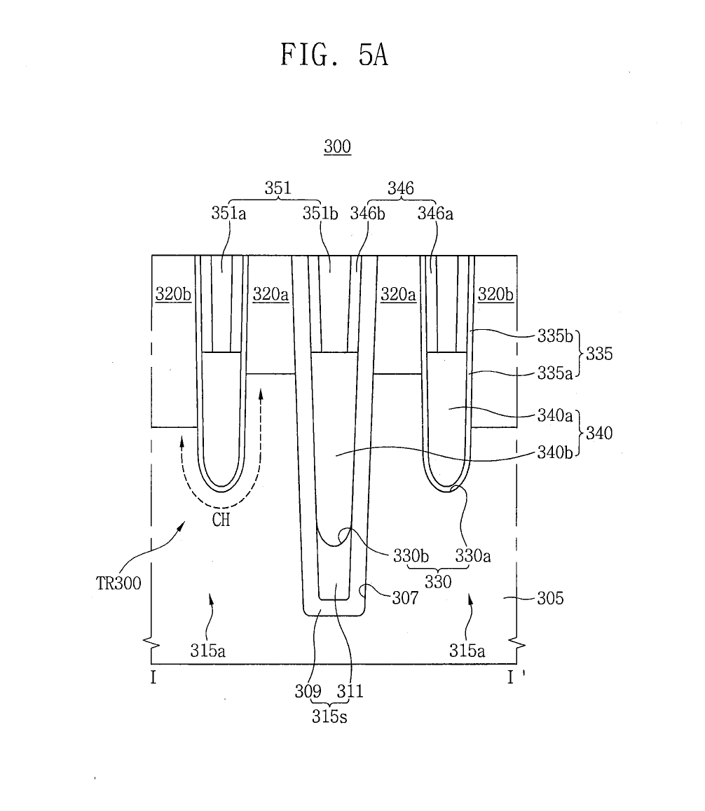

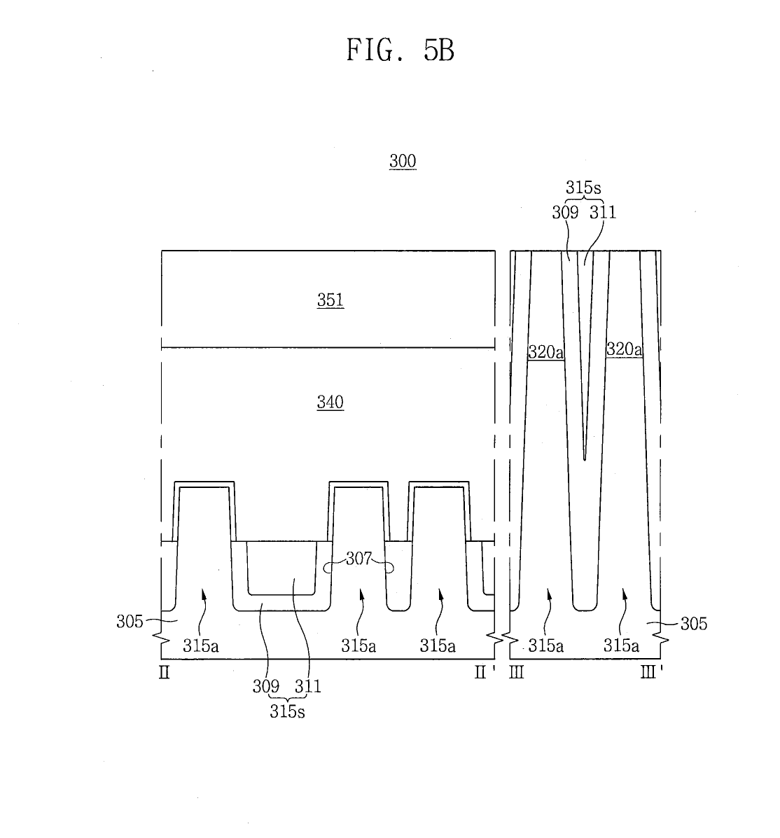

Hereinafter, a semiconductor device 300 in accordance with an embodiment of the inventive concept will be described with reference to FIGS. 5A and 5B with FIG. 1.

Referring to FIGS. 1, 5A, and 5B, a semiconductor device 300 in accordance with yet another embodiment of the inventive concept may include a trench isolation layer 315s disposed in a semiconductor substrate 305 to define an active region 315a. Further, the semiconductor device 300 may include a transistor TR300, a stress pattern 346, and an insulating pattern 351.

The trench isolation layer 315s may be formed of the same structure and material as the trench isolation layer 15s of FIGS. 2A and 2B. For example, the trench isolation layer 315s may include a first isolation layer 309 disposed on an inner wall of an isolation trench 307 located in the semiconductor substrate 305, and a second isolation layer 311 disposed on the first isolation layer 309.

The transistor TR300 may include a gate electrode 340, a gate dielectric layer 335, a first source/drain region 320a, and a second source/drain region 320b. A channel area CH of the transistor TR300 may be defined in the active region 315a which is located between the first and second source/drain regions 320a and 320b, and located in a lower portion of the gate electrode 340.

The gate electrode 340 may be the same as the gate electrode 40 of FIGS. 2A and 2B, the gate dielectric layer 335 may be the same as the gate dielectric layer 35 of FIGS. 2A and 2B, and the first and second source/drain regions 320a and 320b may be the same as the first and second source/drain regions 20a and 20b of FIGS. 2A and 2B. For example, the gate electrode 340 may be disposed in a gate trench 330 to cross the active region 315a and extend onto the trench isolation layer 315s, the gate dielectric layer 335 may include a portion disposed between the gate electrode 340 and the active region 315a, and the first and second source/drain regions 320a and 320b may be disposed in the active region 315a located at both sides of the gate trench 330.

The stress pattern 346 and the insulating pattern 351 may be disposed on the gate electrode 340.

The stress pattern 346 may be disposed in the gate trench 330 of an upper portion of the gate electrode 340, and may be disposed at a lower level than an upper surface of the active region 315a. The stress pattern 346 may have a first portion 346a and a second portion 346b. The first portion 346a of the stress pattern 346 may be disposed on an upper portion of a first portion 340a of the gate electrode 340 located in the active region 315a, and the second portion 346b of the stress pattern 346 may be disposed on an upper portion of a second portion 340b of the gate electrode 340 located in the trench isolation layer 315s.

The stress pattern 346 may face the first source/drain region 320a and/or the second source/drain region 320b. The stress pattern 346 may be interposed between the insulating pattern 351 and the active region 315a. The stress pattern 346 may be disposed closer to the first and second source/drain regions 320a and 320b than the insulating pattern 351. The stress pattern 346 may be disposed between the first and second source/drain regions 320a and 320b and the insulating pattern 351. The stress pattern 346 may be formed of the same material as the stress pattern 146 of FIGS. 3A and 3B. For example, the stress pattern 346 may be formed of a material having a smaller residual stress value than the second isolation layer 311, for example, silicon nitride. The insulating pattern 351 may be formed of the same material as the insulating pattern 151 of FIGS. 3A and 3B.

The gate dielectric layer 335 may include a first portion 335a interposed between the gate electrode 340 and the active region 315a, and a second portion 335b interposed between the stress pattern 346 and the active region 315a.

The stress pattern 346 may improve a performance of the transistor TR300 by improving the resistance characteristics of the transistor TR300. The stress pattern 346 may improve a performance of the transistor TR300 by increasing effective mobility of the transistor TR300. The stress pattern 346 may improve a performance of the transistor TR300 by increasing Ion (on-current) of the transistor TR300.

Hereinafter, a method of forming semiconductor devices in accordance with embodiments of the inventive concept will be described.

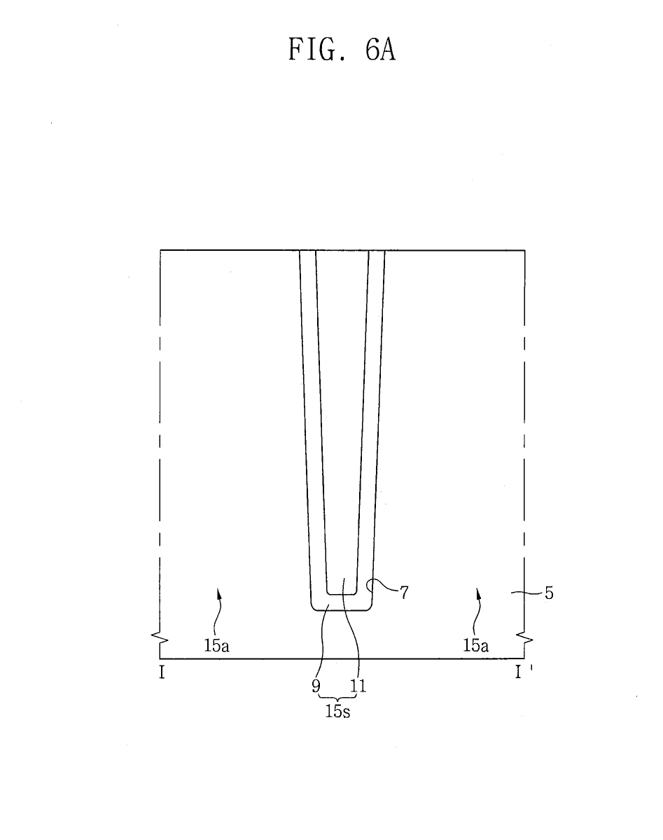

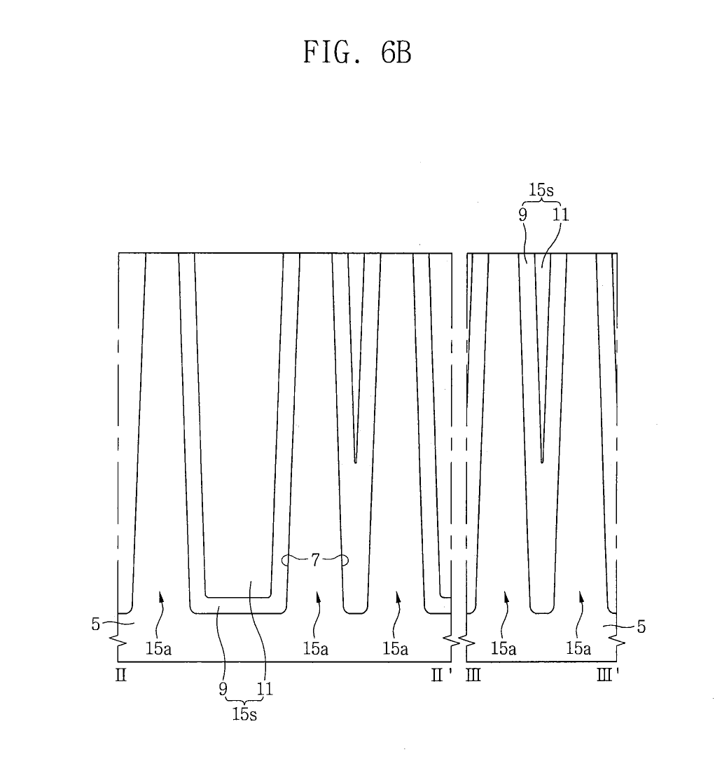

FIGS. 6A, 6B, 7A, 7B, 8A, 8B, 9A, and 9B are cross-sectional views showing a method of forming a semiconductor device in accordance with an embodiment of the inventive concept. FIGS. 6A, 7A, 8A, and 9A are cross-sectional views showing an area taken along the line IT of FIG. 1, and FIGS. 6B, 7B, 8B, and 9B are cross-sectional views showing an area taken along the line II-II′ of FIG. 1 and an area taken along the line of FIG. 1.

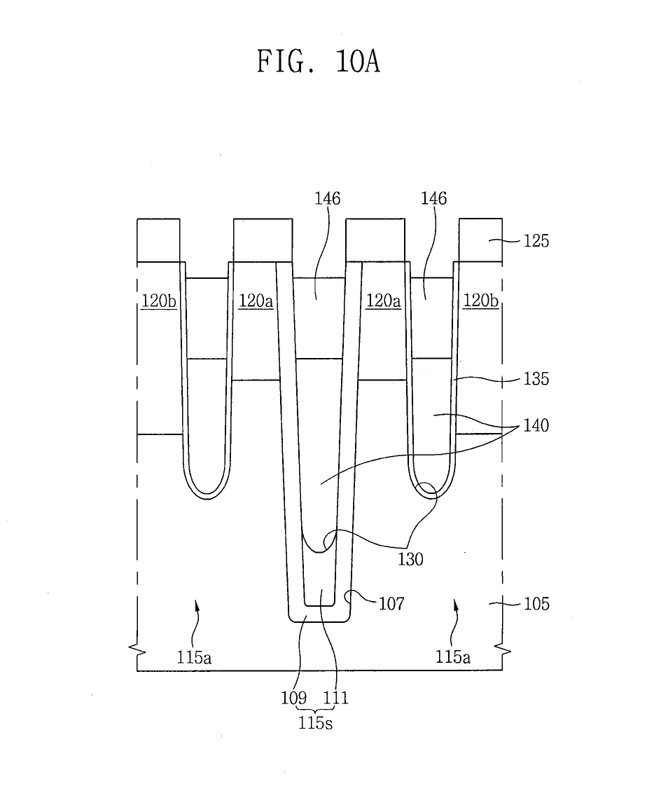

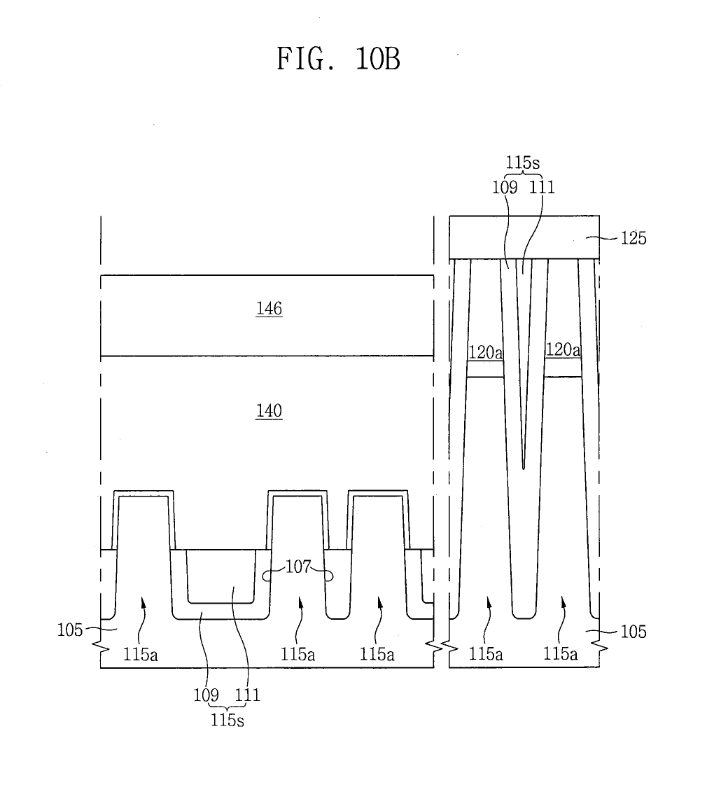

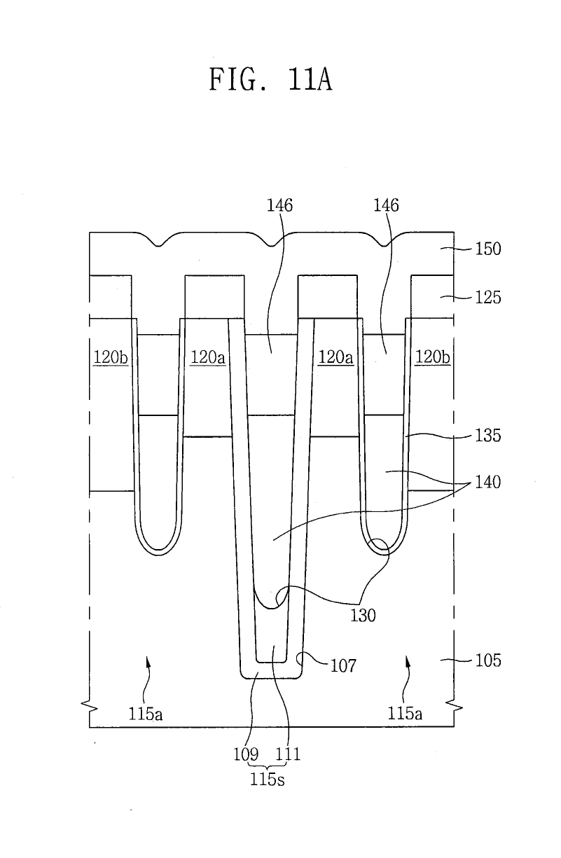

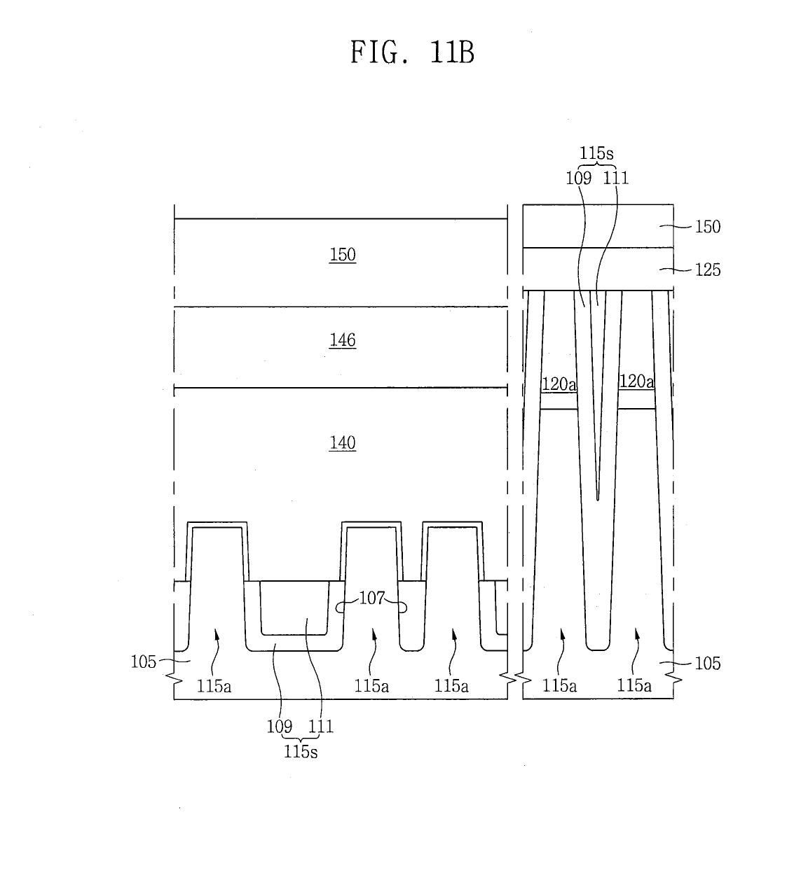

FIGS. 10A, 10B, 11A, and 11B are cross-sectional views showing a method of forming a semiconductor device in accordance with an embodiment of the inventive concept. FIGS. 10A and 11A are cross-sectional views showing an area taken along the line IT of FIG. 1, and FIGS. 10B and 11B are cross-sectional views showing an area taken along the line II-IP of FIG. 1 and an area taken along the line of FIG. 1.

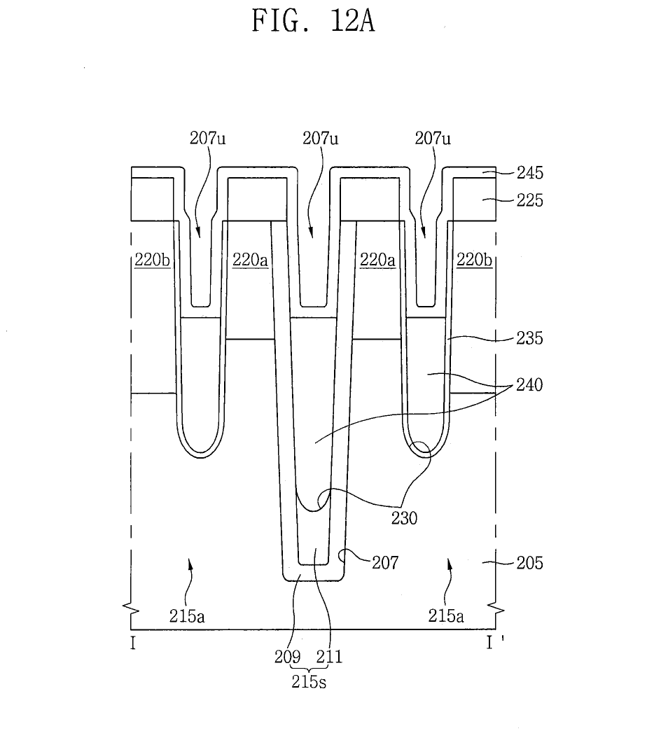

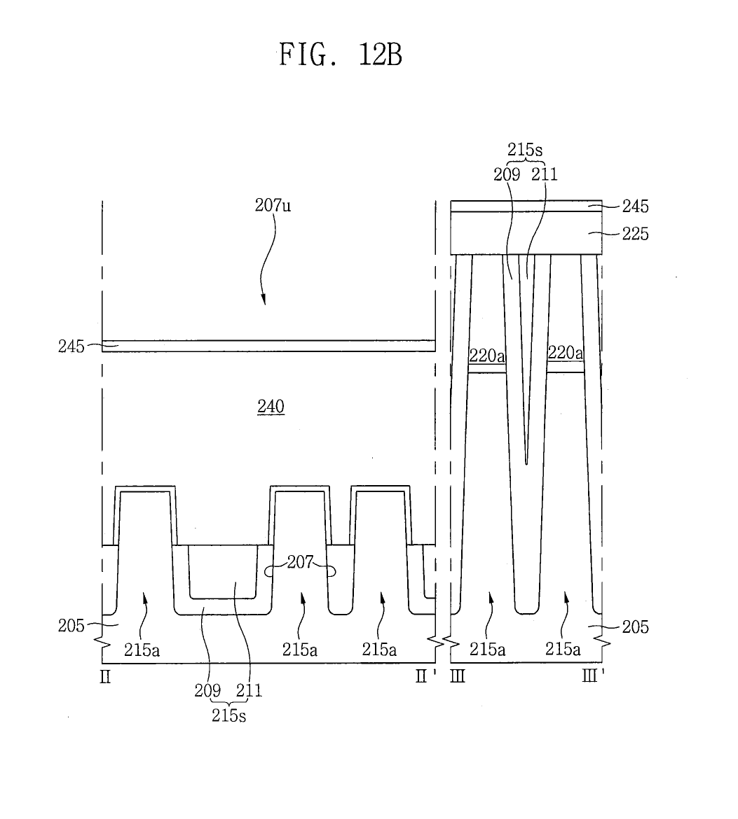

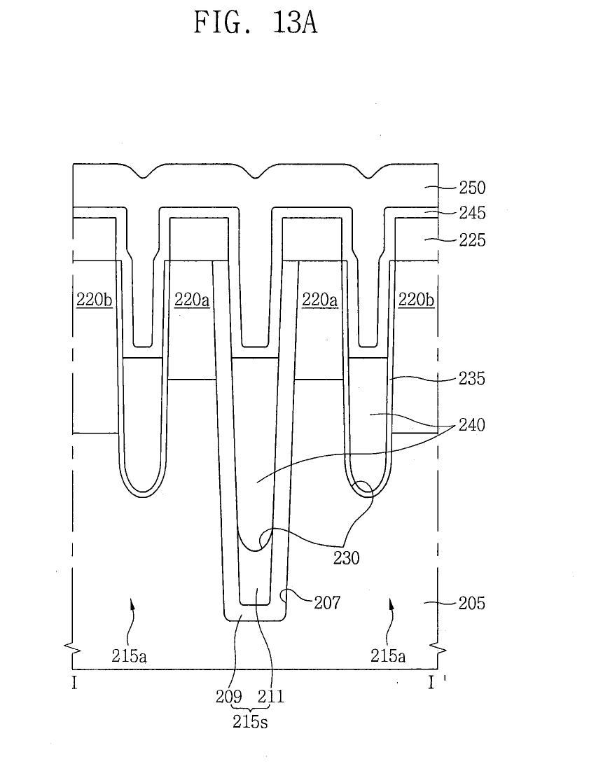

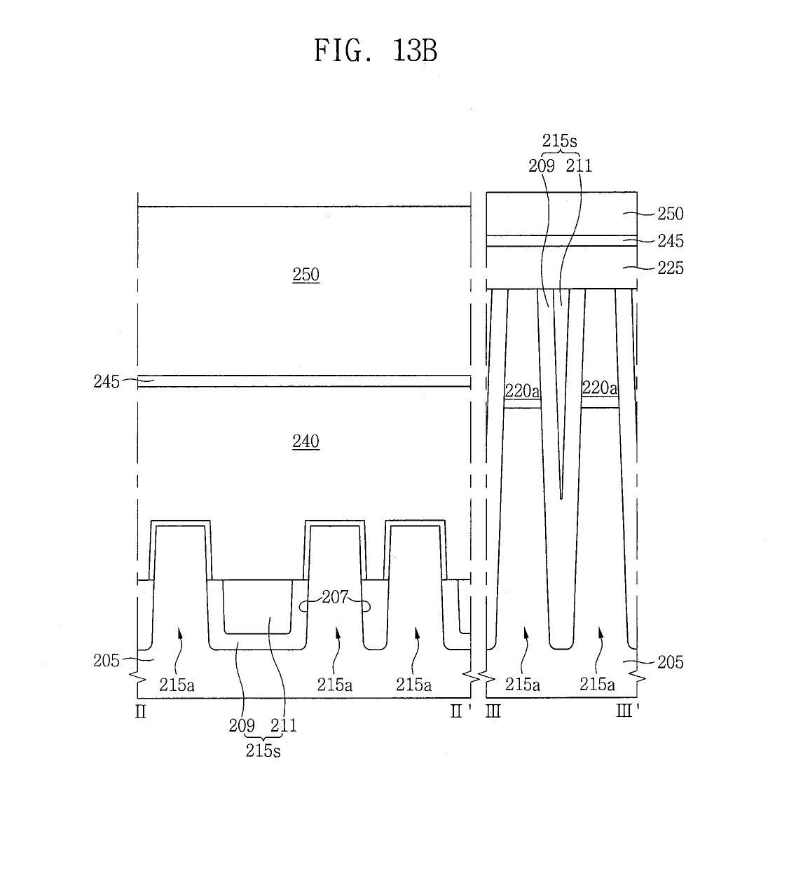

FIGS. 12A, 12B, 13A, and 13B are cross-sectional views showing a method of forming a semiconductor device in accordance with still another embodiment of the inventive concept. FIGS. 12A and 13A are cross-sectional views showing an area taken along the line IT of FIG. 1, and FIGS. 12B and 13B are cross-sectional views showing an area taken along the line II-II′ of FIG. 1 and an area taken along the line of FIG. 1.

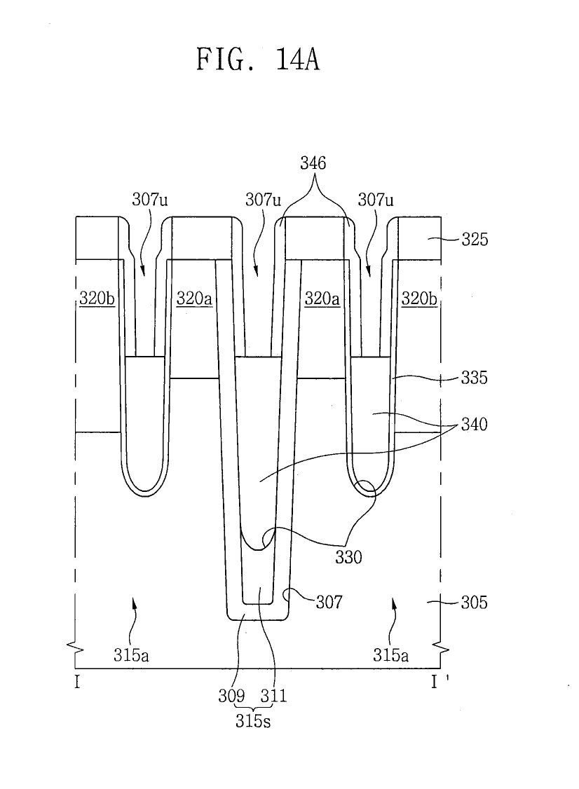

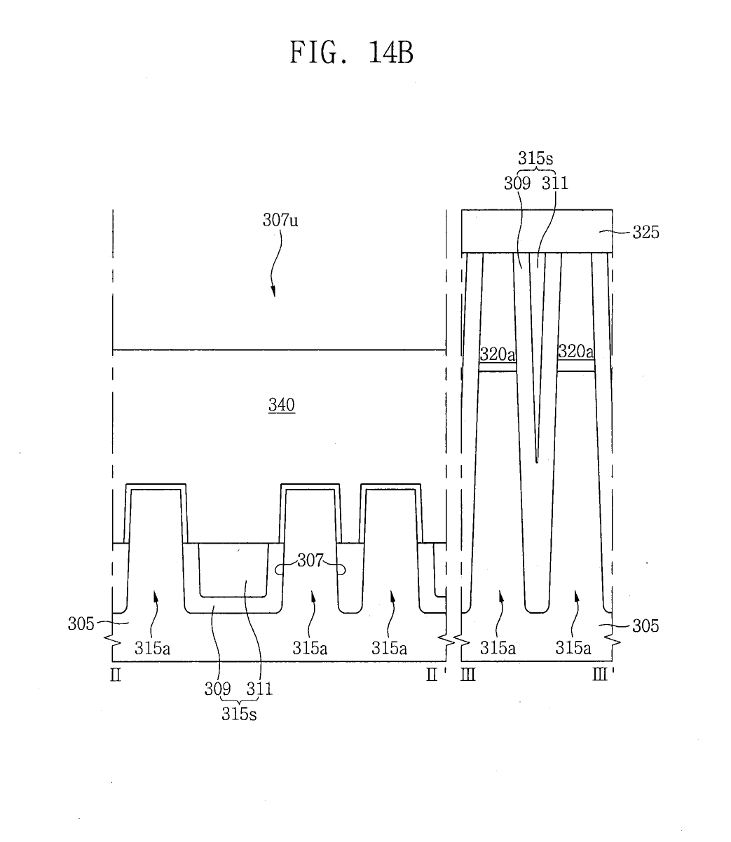

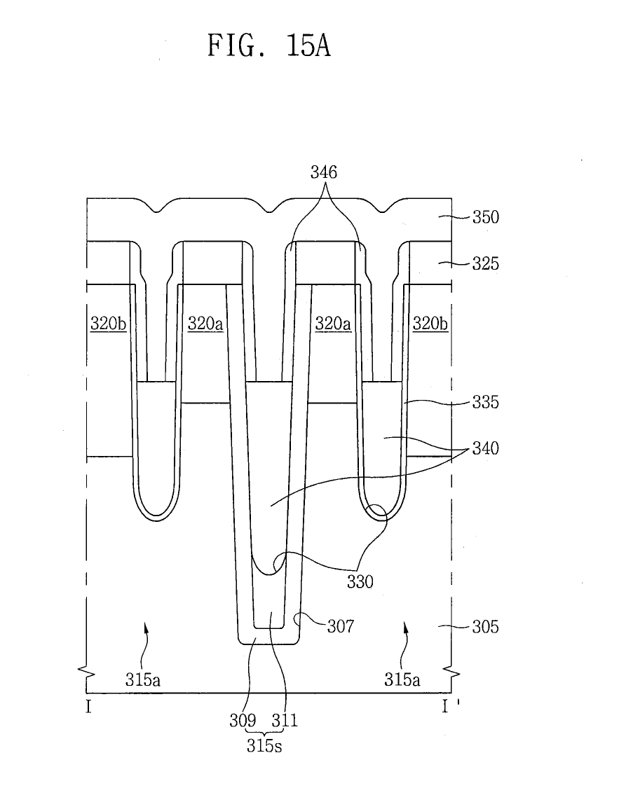

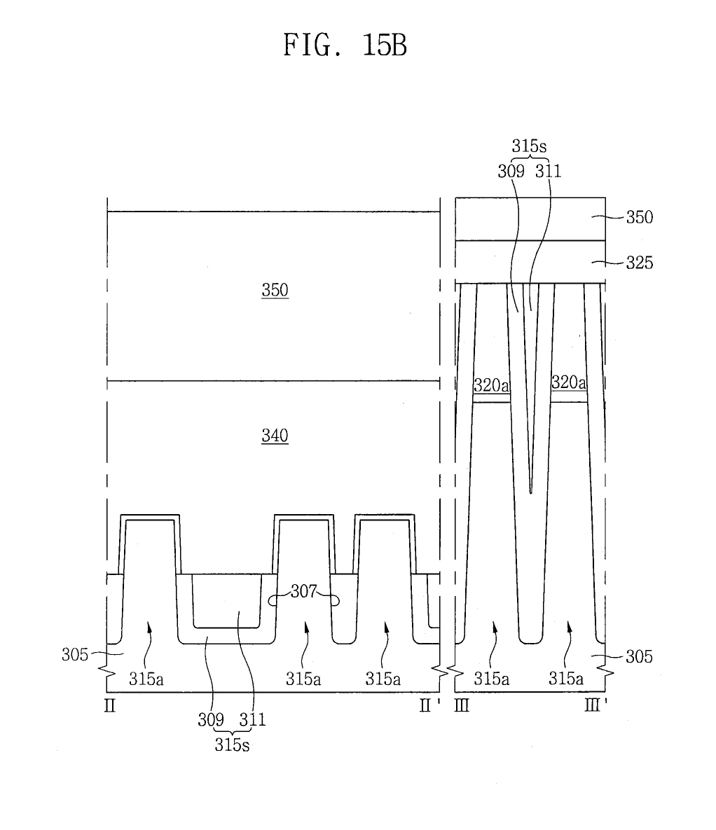

FIGS. 14A, 14B, 15A, and 15B are cross-sectional views showing a method of forming a semiconductor device in accordance with an embodiment of the inventive concept. FIGS. 14A and 15A are cross-sectional views showing an area taken along the line IT of FIG. 1, and FIGS. 14B and 15B are cross-sectional views showing an area taken along the line II-IP of FIG. 1 and an area taken along the line of FIG. 1.

First, an example of a method of forming a semiconductor device described in FIGS. 2A and 2B in accordance with an embodiment of the inventive concept will be described with reference to FIGS. 6A, 6B, 7A, 7B, 8A, 8B, 9A, and 9B.

Referring to FIGS. 1, 6A, and 6B, a method of forming a semiconductor device in accordance with an embodiment of the inventive concept may include forming a trench isolation layer 15s to define an active region 15a in a semiconductor substrate 5.

The semiconductor substrate 5 may be a substrate formed of a semiconductor material such as silicon, etc. The trench isolation layer 15s may include a first isolation layer 9 and a second isolation layer 11 located on the first isolation layer 9. The forming of the trench isolation layer 15s may include forming an isolation trench 7 in the semiconductor substrate 5, forming the first isolation layer 9 on the substrate having the isolation trench 7, forming the second isolation layer 11 on the first isolation layer 9, and planarizing the first and second isolation layers 9 and 11. The first isolation layer 9 may be conformally formed on the substrate having the isolation trench 7. Therefore, the first isolation layer 9 may conformally cover an inner wall of the isolation trench 7. The second isolation layer 11 may be formed on the first isolation layer 9, and may fill the isolation trench 7. The first isolation layer 9 may be formed of silicon oxide, and the second isolation layer 11 may be formed of silicon nitride.

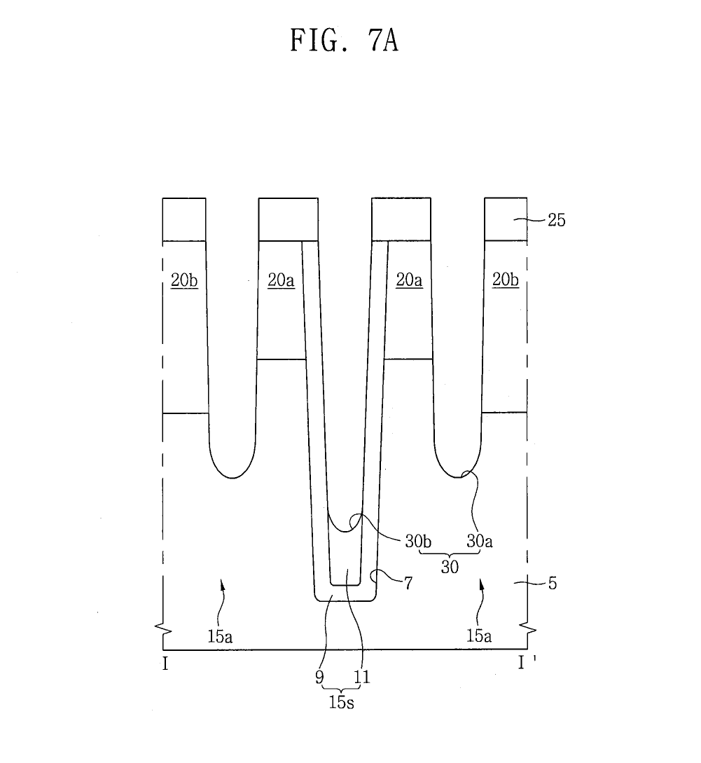

Referring to FIGS. 1, 7A, and 7B, a method of forming a semiconductor device in accordance with an embodiment of the inventive concept may include forming first and second source/drain regions 20a and 20b, and a gate trench 30. For example, the forming of the first and second source/drain regions 20a and 20b, and the gate trench 30 may include forming an impurity area in the active region 15a, forming a gate mask 25 having an opening portion to cross the active region 15a and extend onto the trench isolation layer 15s, and forming the gate trench 30 by etching the active region 15a and the trench isolation layer 15s using the gate mask 25 as an etching mask.

The active region 15a may be a first conductivity type, and the impurity area may be a second conductivity type. For example, the active region 15a may have p-type conductivity, and the impurity area may have n-type conductivity. The impurity area may be formed to the first source/drain region 20a and the second source/drain region 20b by being separated by the gate trench 30.

The first source/drain region 20a and the second source/drain region 20b may be formed in the active region 15a located at both sides of the gate trench 30. A junction depth of the second source/drain region 20b may be deeper than a junction depth of the first source/drain region 20a.

The gate trench 30 may have a first portion 30a located in the active region 15a, and a second portion 30b located in the trench isolation layer 15s. The second portion 30b of the gate trench 30 may have a bottom surface located at a lower level than the first portion 30a of the gate trench 30. The second portion 30b of the gate trench 30 may expose side surfaces of the active region 15a located under the first portion 30a of the gate trench 30.

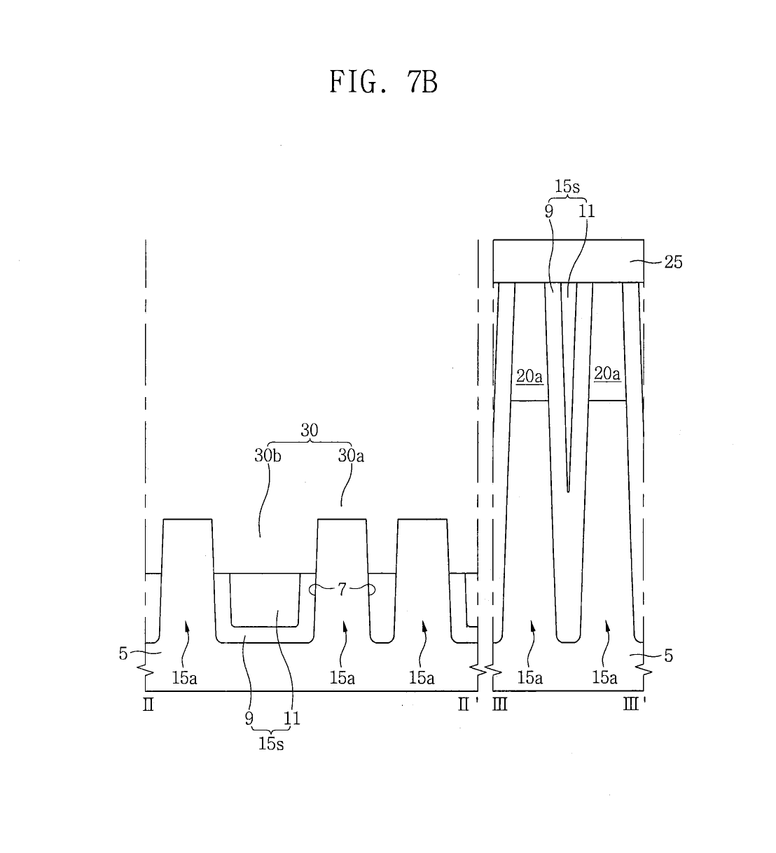

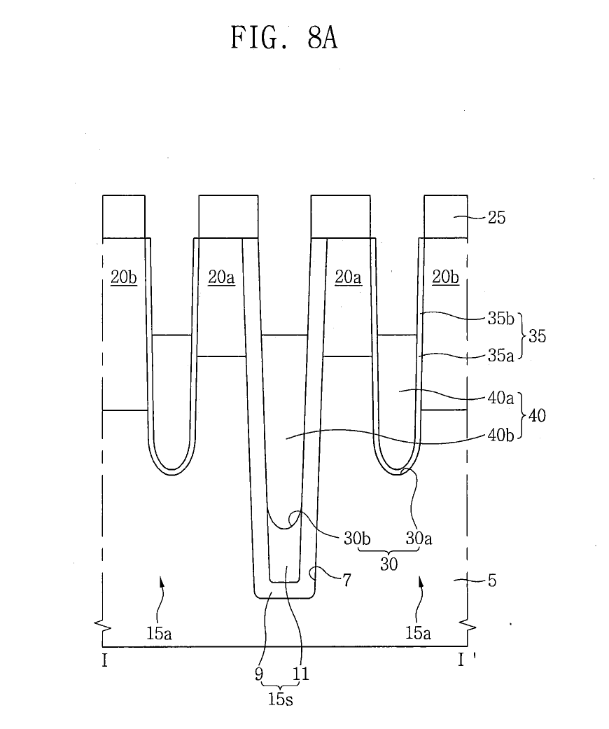

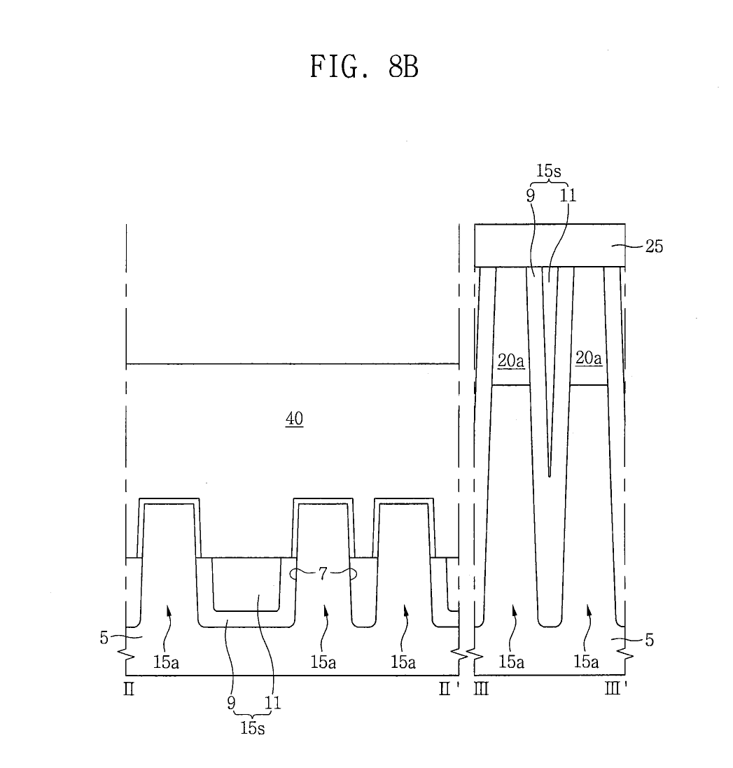

Referring to FIGS. 1, 8A, and 8B, a method of forming a semiconductor device in accordance with an embodiment of the inventive concept may include forming a gate dielectric layer 35, and a gate electrode 40.

The forming of the gate dielectric layer 35 may include forming a dielectric material on a surface of the active region 15a exposed by the gate trench 30. The forming of the gate dielectric layer 35 may include forming a thermal oxide layer on the surface of the active region 15a exposed by the gate trench 30 using a thermal oxidation process. The gate dielectric layer 35 may be formed of silicon oxide or nitrogen-doped silicon oxide. The gate dielectric layer 35 may be formed to a smaller thickness than the first isolation layer 9 of the trench isolation layer 15s.

The forming of the gate electrode 40 may include forming a gate conductive layer on the substrate having the gate dielectric layer 35, and partially etching the gate conductive layer. The gate electrode 40 may be formed of a conductive material such as tungsten, titanium nitride, tantalum nitride, or tungsten nitride. Some portion of the gate electrode 40 may face some portion of the first source/drain region 20a and/or some portion of the second source/drain region 20b.

The gate electrode 40 may have a first portion 40a located in the active region 15a, and a second portion 40b located in the trench isolation layer 15s. The second portion 40b of the gate electrode 40 may have a bottom surface located at a lower level than the first portion 40a of the gate electrode 40. The gate dielectric layer 35 may have a first portion 35a interposed between the gate electrode 40 and the active region 15a, and a second portion 35b located at a higher level than the gate electrode 40.

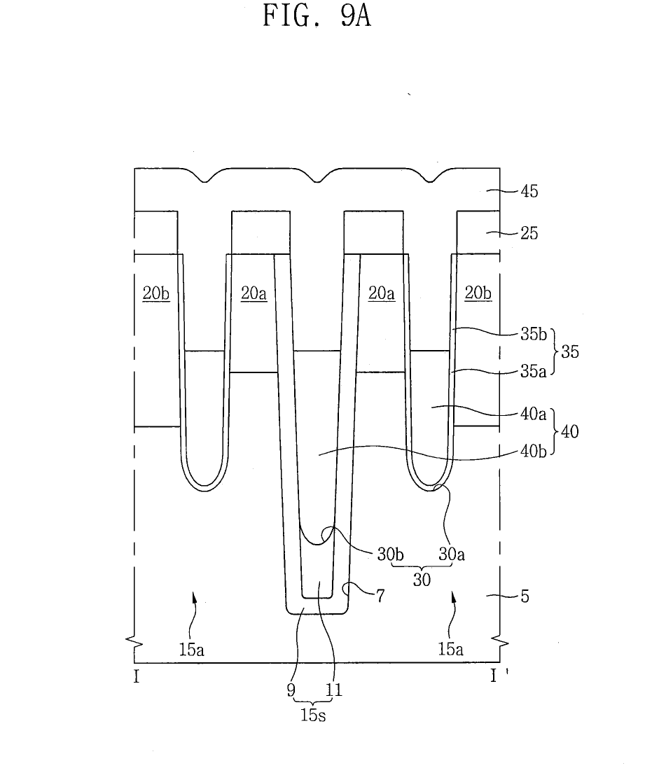

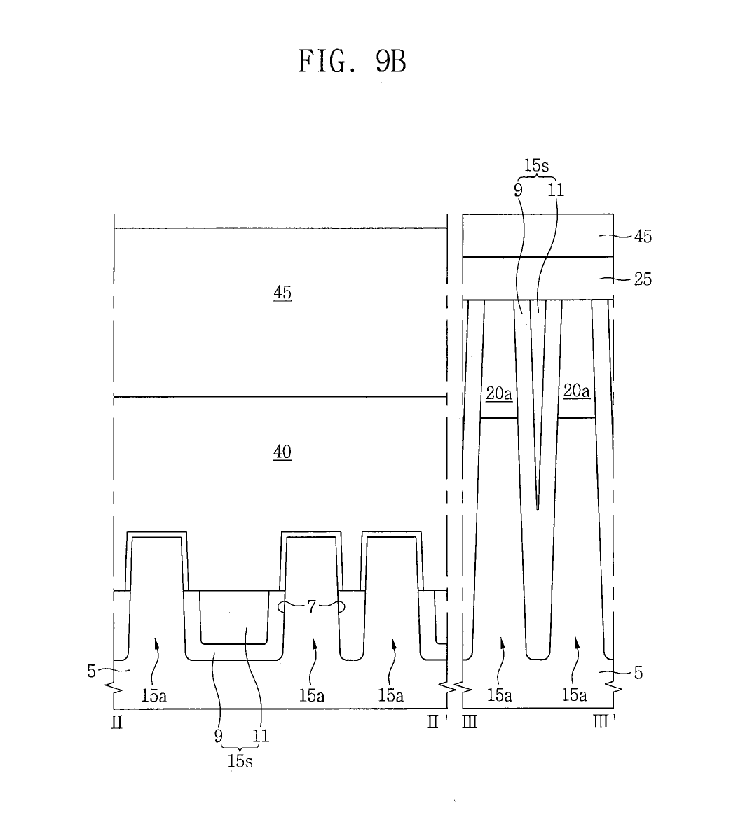

Referring to FIGS. 1, 9A, and 9B, a method of forming a semiconductor device in accordance with an embodiment of the inventive concept may include forming a stress layer 45. The forming of the stress layer 45 may include forming to fill an empty space of the gate trench 30 on the substrate having the gate electrode 40.

The forming of the stress layer 45 may include forming of a material of which residual stress is lower than that of the second isolation layer 11 of the trench isolation layer 15s. For example, the second isolation layer 11 may be formed of silicon nitride, and the stress layer 45 may be formed to include at least one of SiBN, SiBCN, SiOCN, SiOBN, SiON, BN, or SiCN, of which residual stress is lower than that of silicon nitride (or residual stress value is smaller).

In an embodiment, the forming of the stress layer 45 may include forming of a material of which residual stress and permittivity are lower than those of silicon nitride. For example, the forming of the stress layer 45 may include forming to include at least one of SiBN, SiOCN, SiOBN, SiON, or BN.

In an embodiment, the forming of the stress layer 45 may include forming of an SiBN material of which residual stress and permittivity are lowered compared to those of silicon nitride by adding boron (B) as impurities into the silicon nitride.

In an embodiment, the forming of the stress layer 45 may include forming of a material of which residual stress and permittivity are lowered compared to those of silicon nitride by adding oxygen (O) or carbon (C) together with boron (B) as impurities into the silicon nitride.

Referring again to FIGS. 2A and 2B, a method of forming a semiconductor device in accordance with an embodiment of the inventive concept may include forming a stress pattern 46.

The forming of the stress pattern 46 may include planarizing the stress layer (45 in FIGS. 9A and 9B). The planarizing thereof may be conducted using a chemical mechanical planarization (CMP) process and/or an etch-back process. While the stress layer (45 in FIGS. 9A and 9B) is planarized, the gate mask 25 may be removed. Or, after the stress layer (45 in FIGS. 9A and 9B) is planarized, the gate mask 25 may be removed using an etching process.

Therefore, the semiconductor device 1 as described in FIGS. 2A and 2B may be formed.

A method of forming a semiconductor device described with reference to FIGS. 3A and 3B in accordance with an embodiment of the inventive concept will be described with reference to FIGS. 10A to 11B with FIG. 1.

Referring to 1, 10A, and 10B, a method of forming a semiconductor device in accordance with another embodiment of the inventive concept may include forming a trench isolation layer 115s in a semiconductor substrate 105 to define an active region 115a by proceeding the same process as described with reference to FIGS. 6A and 6B, forming a gate mask 125, a gate trench 130, and first and second source/drain regions 120a and 120b by proceeding the same process as described with reference to FIGS. 7A and 7B, and forming a gate dielectric layer 135 and a gate electrode 140 by proceeding the same process as described with reference to FIGS. 8A and 8B.

A method of forming a semiconductor device in accordance with an embodiment of the inventive concept may include forming the stress layer (45 in FIGS. 9A and 9B) by proceeding the same process as described with reference to FIGS. 9A and 9B, and forming a stress pattern 146 by partially etching the stress layer (45 in FIGS. 9A and 9B). The stress pattern 146 may be formed on the gate electrode 140. An upper surface of the stress pattern 146 may be formed at a lower level than an upper surface of the active region 115a.

Referring to FIGS. 1, 11A, and 11B, a method of forming a semiconductor device in accordance with an embodiment of the inventive concept may include forming an insulating layer 150 on the substrate having the stress pattern 146.

The forming of the insulating layer 150 may include forming of a different material from the stress pattern 146. The forming of the insulating layer 150 may include forming of a material having an etch selectivity with respect to the stress pattern 146. The forming of the insulating layer 150 may include forming of a material having a higher etch resistance than the stress pattern 146. For example, the stress pattern 146 may be formed of silicon nitride to which boron is added as impurities, and the insulating layer 150 may be formed of silicon nitride to which boron is not added.

Referring again to FIGS. 3A and 3B, a method of forming a semiconductor device in accordance with an embodiment of the inventive concept may include forming an insulating pattern 151 by planarizing the insulating layer (150 in FIGS. 11A and 11B). The planarizing thereof may be conducted using a CMP process and/or an etch-back process.

While the insulating layer (150 in FIGS. 11A and 11B) is planarized, the gate mask 125 may be removed. Or, after the insulating layer (150 in FIGS. 11A and 11B) is planarized, the gate mask 125 may be removed using an etching process. The insulating pattern 151, while the gate mask 125 is removed using an etching process, may protect the stress pattern 146.

Therefore, the semiconductor device 100 as described in FIGS. 3A and 3B may be formed.

Next, a method of forming a semiconductor device described with reference to FIGS. 4A and 4B in accordance with an embodiment of the inventive concept will be described with reference to FIGS. 12A to 13B with FIG. 1.

Referring to FIGS. 1, 12A, and 12B, a method of forming a semiconductor device in accordance with an embodiment of the inventive concept may include forming a trench isolation layer 215s in a semiconductor substrate 205 to define an active region 215a by proceeding the same process as described with reference to FIGS. 6A and 6B, forming a gate mask 225, a gate trench 230, and first and second source/drain regions 220a and 220b by proceeding the same process as described with reference to FIGS. 7A and 7B, and forming a gate dielectric layer 235 and a gate electrode 240 by proceeding the same process as described with reference to FIGS. 8A and 8B.

A method of forming a semiconductor device in accordance with an embodiment of the inventive concept may include forming a stress layer 245 on the substrate having the gate electrode 240. The forming of the stress layer 245 may include conformally forming on the substrate having the gate electrode 240. The stress layer 245 may be formed not to fully fill a portion 207u of a gate trench 230 located on an upper portion of the gate electrode 240. The stress layer 245 may be formed to a smaller thickness than a 1/2 width of the gate trench 230. The stress layer 245 may be formed of the same material as the stress layer 45 described in FIGS. 9A and 9B.

Referring to FIGS. 1, 13A, and 13B, a method of forming a semiconductor device in accordance with an embodiment of the inventive concept may include forming an insulating layer 250 on the substrate having the stress layer 245. The insulating layer 250 may fill the gate trench 230 located on the upper portion of the gate electrode 240. The forming of the insulating layer 250 may include forming of a different material from the stress layer 245. The forming of the insulating layer 250 may include forming of a material having an etch selectivity with respect to the stress layer 245. The forming of the insulating layer 250 may include forming of a material having a higher etch resistance than the stress layer 245. For example, the stress layer 245 may be formed of silicon nitride to which boron is added as impurities, and the insulating layer 250 may be formed of silicon nitride to which boron is not added.

Referring again to FIGS. 4A and 4B, a method of forming a semiconductor device in accordance with an embodiment of the inventive concept may include planarizing the insulating layer 250 and the stress layer 245. The planarizing thereof may be conducted using a CMP process and/or an etch-back process. The insulating layer 250 may be formed to an insulating pattern 251 by being planarized, and the stress layer 245 may be formed to a stress pattern 246 by being planarized.

While the stress layer 245 and the insulating layer 250 are planarized, the gate mask 225 may be removed. Or, after the stress layer 245 and the insulating layer 250 are planarized, the gate mask 225 may be removed using an etching process.

Therefore, the semiconductor device 200 as described in FIGS. 4A and 4B may be formed.

Next, a method of forming a semiconductor device described with reference to FIGS. 5A and 5B in accordance with an embodiment of the inventive concept will be described with reference to FIGS. 14A to 15B with FIG. 1.

Referring to FIGS. 1, 14A, and 14B, a method of forming a semiconductor device in accordance with an embodiment of the inventive concept may include forming a trench isolation layer 315s in a semiconductor substrate 305 to define an active region 315a by proceeding the same process as described with reference to FIGS. 6A and 6B, forming a gate mask 325, a gate trench 330, and first and second source/drain regions 320a and 320b by proceeding the same process as described with reference to FIGS. 7A and 7B, and forming a gate dielectric layer 335 and a gate electrode 340 by proceeding the same process as described with reference to FIGS. 8A and 8B.

A method of forming a semiconductor device in accordance with an embodiment of the inventive concept may include forming the same stress layer (245 in FIG. 12A) as described in FIGS. 12A and 12B on the substrate having the gate electrode 340, and forming a stress pattern 346 by anisotropically etching the stress layer (245 in FIG. 12A). The stress pattern 346 may be formed on a side wall of a portion 307u of a gate trench 330 located on an upper portion of the gate electrode 340.

Referring to FIGS. 1, 15A, and 15B, a method of forming a semiconductor device in accordance with an embodiment of the inventive concept may include forming an insulating layer 350 on the substrate having the stress pattern 346.

Referring again to 5A and 5B, a method of forming a semiconductor device in accordance with yet another embodiment of the inventive concept may include forming an insulating pattern 351 by planarizing the insulating layer 350. The insulating pattern 351 may be formed between the stress pattern 346 located on the gate electrode 340. In an embodiment, the insulating layer 350 is planarized, the gate mask 325 may be removed. Alternatively, after the insulating layer 350 is planarized, the gate mask 325 may be removed using an etching process.

Therefore, the semiconductor device 300 as described in FIGS. 5A and 5B may be formed.

### Experimental Example 1

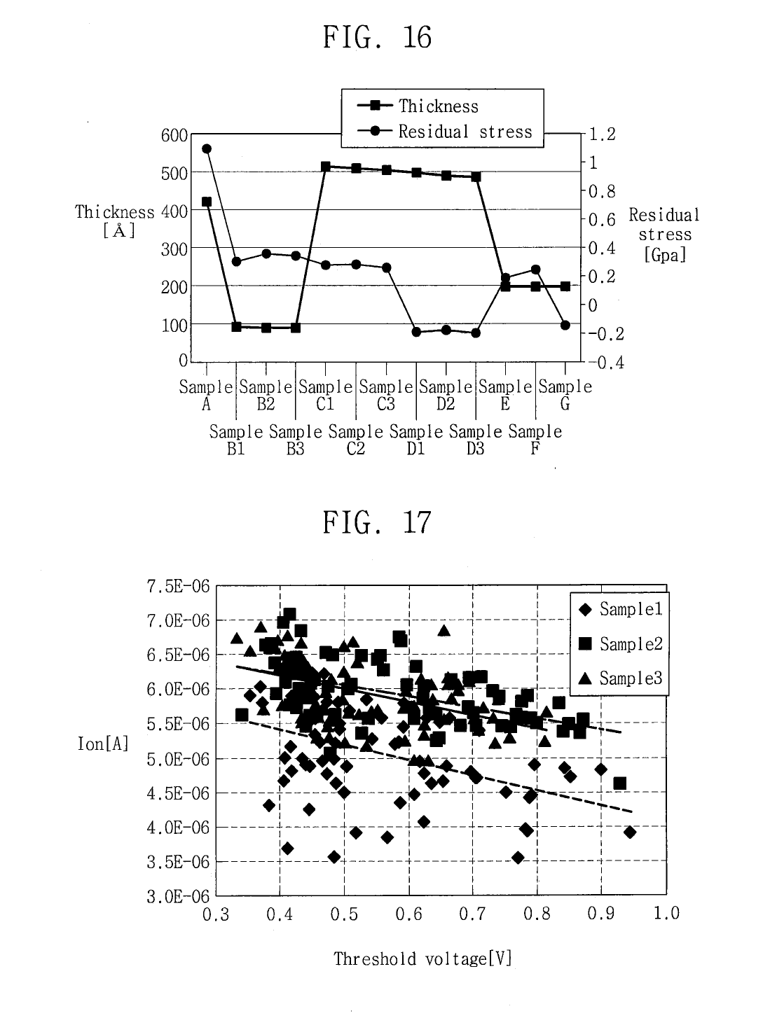

FIG. 16 is a view for describing the residual stress characteristics of a stress pattern of a semiconductor device in accordance with an embodiment of the inventive concept. FIG. 16 is a view showing film thicknesses and residual stress of an SiN layer, an SiBN layer, and an SiBCN layer.

Referring to FIG. 16, sample A is an SiN sample as a reference sample. Samples B1, B2, B3, C1, C2, C3, D1, D2, D3, E, F, and G may be materials to form the stress patterns 46, 146, 246, and 346 of the semiconductor devices 1, 100, 200, and 300 in accordance with the inventive concept.

The sample A is an SiN sample having a film thickness of about 420 Å and a residual stress of about 1.1 GPa.

The samples B1, B2, B3, C1, C2, and C3 are SiBN samples having permittivity k=5.5.

The samples D1, D2, and D3 are SiBN samples having permittivity k=4.5.

The sample E is an SiBCN sample having permittivity k=5.5, the sample F is an SiBCN sample having permittivity k=5.0, and the sample G is an SiBCN sample having permittivity k=4.5.

The samples B1, B2, B3, C1, C2, and C3 are samples to see changes in a residual stress according to changes in the thickness of an SiBN layer.

The sample B1 may have a film thickness of about 90 Å, and a residual stress of about 0.30 GPa. The sample B2 may have a film thickness of about 90 Å, and a residual stress of about 0.36 GPa. The sample B3 may have a film thickness of about 90 Å, and a residual stress of about 0.34 GPa.

The sample C1 may have a film thickness of about 515 Å, and a residual stress of about 0.28 GPa. The sample C2 may have a film thickness of about 510 Å, and a residual stress of about 0.28 GPa. The sample C3 may have a film thickness of about 505 Å, and a residual stress of about 0.26 GPa.

Referring to the samples B1, B2, and B3, and the samples C1, C2, and C3, a degree of changes in the residual stress of the stress pattern may be smaller than a degree of changes in the thickness of the stress pattern. While SiBN layers of the samples C1, C2, and C3 have about five times greater thickness than SiBN layers of the samples B1, B2, and B3, it shows that the SiBN layers of the samples C1, C2, and C3 have a similar or slightly lower residual stress than the SiBN layers of the samples B1, B2, and B3.

The samples D1, D2, and D3 are samples to see changes in a residual stress according to changes in permittivity of an SiBN layer.

The sample D1 may have a film thickness of about 500 Å, and a residual stress of about −0.19 GPa. The sample D2 may have a film thickness of about 490 Å, and a residual stress of about −0.17 GPa. The sample D3 may have a film thickness of about 485 Å, and a residual stress of about −0.20 GPa.

Referring to the samples B1, B2, B3, C1, C2, and C3, and the samples D1, D2, and D3, it shows that changes in residual stress values according to the changes in permittivity are greater than the changes of thicknesses. Therefore, the samples D1, D2, and D3, of which permittivity is relatively low, have a lower residual stress than the samples B1, B2, B3, C1, C2, and C3.

The samples E, F, and G are samples to see the residual stress when permittivity is changed without changes in thickness.

The sample E may have a film thickness of about 195 Å, and a residual stress of about 0.19 GPa. The sample F may have a film thickness of about 195 Å, and a residual stress of about 0.25 GPa. The sample G may have a film thickness of about 195 Å, and a residual stress of about −0.14 GPa.

Referring to the samples E, F, and G, it shows that the samples E and F have a residual tensile stress, and the sample G has a residual compressive stress.

Comparing the samples E and F and the sample G, and comparing the samples C1, C2, and C3 and the samples D1, D2, and D3, when the permittivity is lowered from 5.5 k to 4.5 k, it shows that the residual stress is changed from a residual tensile stress to a residual compressive stress.

The samples B1, B2, B3, C1, C2, C3, D1, D2, D3, E, F, and G in accordance with the inventive concept have a smaller residual stress value than the reference sample A.

### Experimental Example 2

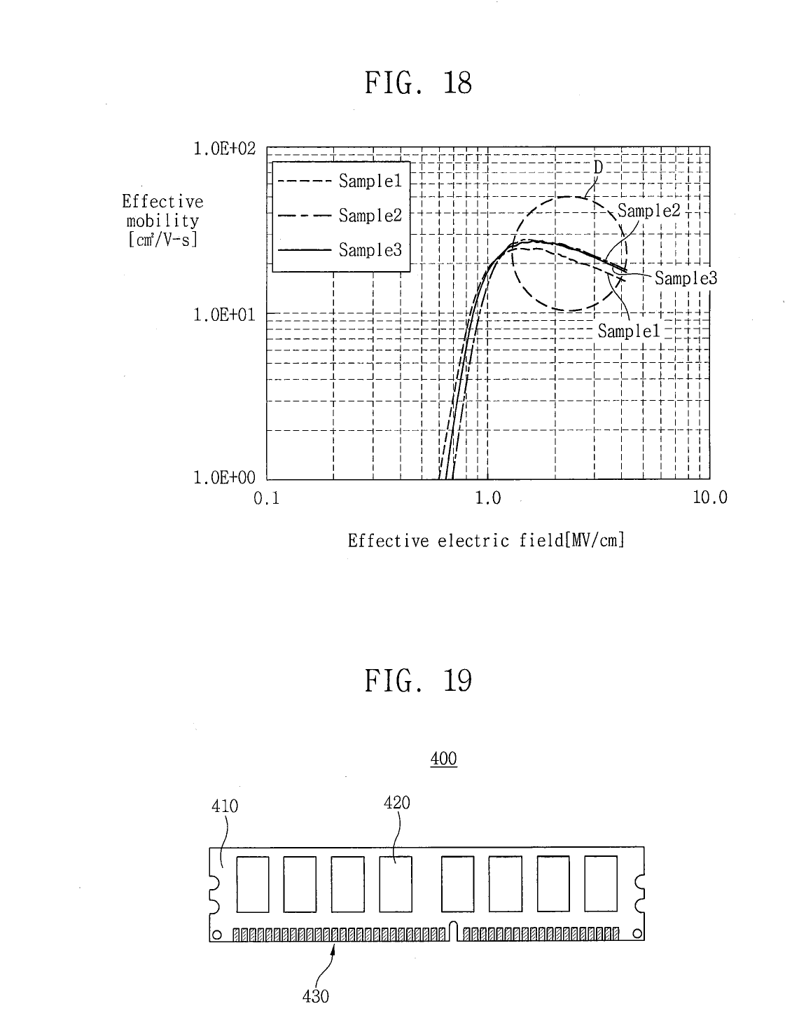

Table 1 is a table for describing the resistance characteristics of a transistor of a semiconductor device in accordance with an embodiment of the inventive concept, FIG. 17 is a view showing the Ion characteristics of a transistor of a semiconductor device in accordance with an embodiment of the inventive concept, and FIG. 18 is a view showing the effective mobility characteristics of a transistor of a semiconductor device in accordance with an embodiment of the inventive concept.

In Table 1, and FIGS. 17 and 18, samples 1, 2, and 3 are samples having the same structure as the transistor TR of the semiconductor device 1 of FIGS. 2A and 2B. The sample 1 is a reference sample to which the stress pattern 46 of the semiconductor device 1 of FIGS. 2A and 2B is not applied and a pattern is formed of an SiN material instead of the stress pattern 46, and the sample 2 and sample 3 are samples in which the stress pattern 46 of the semiconductor device 1 of FIGS. 2A and 2B is formed of an SiBN layer.

TABLE 1

| | Sample 1 | Sample 2 | Sample 3 |
|---|---|---|---|
| Resistance [Ω] | 48600 | 43000 | 42810 |

First, referring to Table 1, a resistance in the Table 1 is a sum of a resistance value of the first source/drain region 20a, a channel resistance of the channel area CH, and a resistance value of the second source/drain region 20b.

Table 1 shows that the samples 2 and 3 have lower resistance values than the sample 1. Therefore, when the stress pattern 46 of the inventive concept is applied, the resistance characteristics of the transistor TR is improved.

FIG. 17 shows that the samples 2 and 3 have the better Ion (on-current) characteristics than the sample 1. Therefore, when the stress pattern 46 of the inventive concept is applied, the Ion characteristics of the transistor TR is improved.

In FIG. 18, reference character “D” may be an area in which a semiconductor device including a transistor operates. FIG. 18 shows that samples 2 and 3 have the better effective mobility characteristics than the sample 1. When the stress pattern 46 of the inventive concept is applied, the effective mobility characteristics of the transistor TR are improved. Therefore, when the stress pattern 46 of the inventive concept is applied, a performance of the transistor TR is improved.

FIG. 19 is a schematic view illustrating a semiconductor module 400 including a semiconductor device in accordance with embodiments of the inventive concept.

Referring to FIG. 19, a semiconductor module 400 may be a memory module including a memory device. The semiconductor module 400 may include a module substrate 410, a plurality of semiconductor devices 420 disposed on the module substrate 410, and a plurality of terminals 430. The terminals 430 may include a conductive metal. The terminals 430 may be electrically connected to the semiconductor devices 420.

The module substrate 410 may be a memory module substrate. The module substrate 410 may include a printed circuit board (PCB) or a wafer.

The semiconductor devices 420 may be memory devices. The semiconductor devices 420 may be dynamic random access memory (DRAM) devices. The semiconductor devices 420 may be a semiconductor device in accordance with one embodiment among the embodiments of the inventive concept, or a semiconductor package including the semiconductor device.

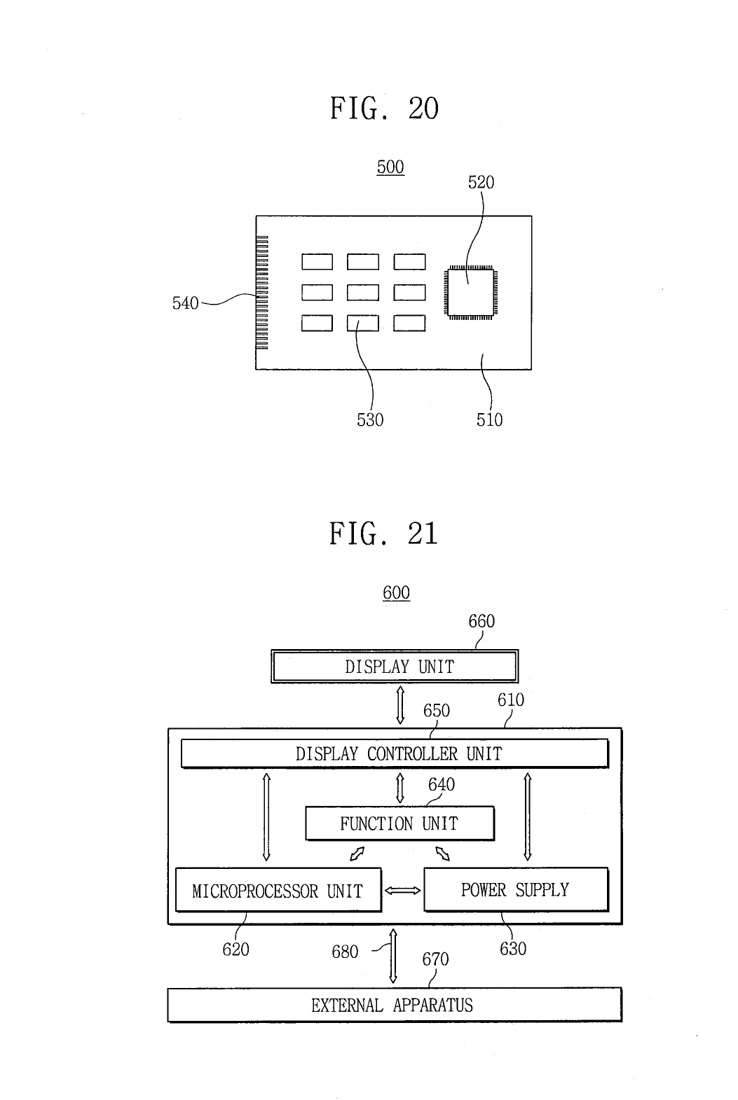

FIG. 20 is a schematic view illustrating a semiconductor module 500 including a semiconductor device in accordance with embodiments of the inventive concept.

Referring to FIG. 20, a semiconductor module 500 may include a semiconductor device 530 formed on a module substrate 510. The semiconductor device 530 may be a semiconductor device or a semiconductor package including the semiconductor device.

The semiconductor module 500 may further include a microprocessor 520 installed on the module substrate 510. Input/output terminals 540 may be disposed on at least one side of the module substrate 510.

FIG. 21 is a conceptual block diagram illustrating an electronic system 600 including a semiconductor device in accordance with an embodiment of the inventive concept.

Referring to FIG. 21, an electronic system 600 may include a body 610. The body 610 may include a microprocessor unit 620, a power supply 630, a function unit 640, and/or a display controller unit 650. The body 610 may be a system board or a motherboard having a PCB, etc.

The microprocessor unit 620 may be a semiconductor device or a semiconductor package including the semiconductor device.

The microprocessor unit 620, the power supply 630, the function unit 640, and the display controller unit 650 may be installed or mounted on the body 610. A display unit 660 may be disposed on an upper surface of the body 610 or outside the body 610. For example, the display unit 660 may be disposed on a surface of the body 610, and display an image processed by the display controller unit 650. The power supply 630 may receive a constant voltage from an external power supply, divide the voltage into various required levels, and supply those voltages to the microprocessor unit 620, the function unit 640, the display controller unit 650, etc. The microprocessor unit 620 may receive a voltage from the power supply 630 to control the function unit 640 and the display unit 660.

The function unit 640 may perform various functions of the electronic system 600. For example, when the electronic system 600 is a mobile electronic product such as a cellular phone, etc., the function unit 640 may include various components to perform wireless communication functions such as dialing, video output to the display unit 660 or voice output to a speaker through communication with an external device 670, and when a camera is included, it may serve as an image processor.

In an embodiment, when the electronic system 600 is connected to a memory card to expand the capacity, the function unit 640 may be a memory card controller. The function unit 640 may send and receive signals to and from the external device 670 through a wired or wireless communication unit 680.

When the electronic system 600 requires a Universal Serial Bus (USB) to extend the functions, the function unit 640 may serve as an interface controller.

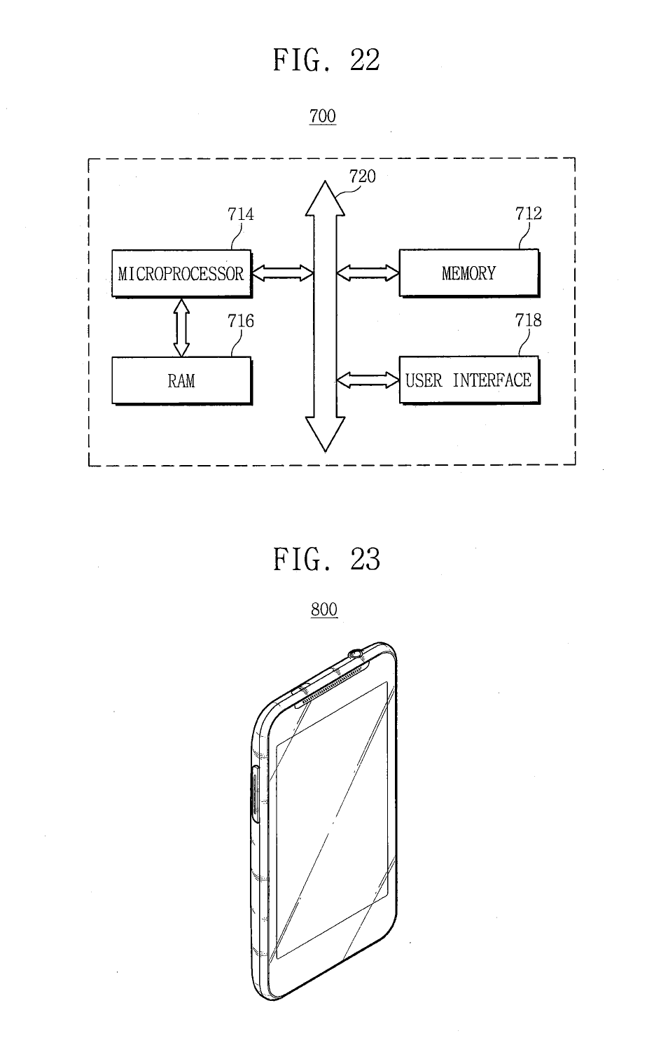

FIG. 22 is a schematic block diagram illustrating an electronic system 700 including a semiconductor device in accordance with an embodiment of the inventive concept.

Referring to FIG. 22, an electronic system 700 may include a semiconductor device in accordance with an embodiment of the inventive concept. The electronic system 700 may be used to manufacture a mobile device or a computer. For example, the electronic system 700 may include a memory system 712, a microprocessor 714, a random access memory (RAM) 716, and a user interface 718 configured to perform data communication using a bus 720. The microprocessor 714 may program and control the electronic system 700. The RAM 716 may be used as an operation memory of the microprocessor 714. The microprocessor 714, the RAM 716, and/or other components may be assembled within a single package. The memory system 712 may be a semiconductor device in accordance with one embodiment among the embodiments of the inventive concept, or a semiconductor package including the semiconductor device.

The user interface 718 may be used to input data to the electronic system 700, or output from the electronic system 700. The memory system 712 may store codes for operating the microprocessor 714, data processed by the microprocessor 714, or data received from the outside. The memory system 712 may include a controller and a memory.

FIG. 23 is a schematic view illustrating a mobile wireless phone 800 including a semiconductor device in accordance with an embodiment of the inventive concept. The mobile wireless phone 800 may include a semiconductor device in accordance with an embodiment of the inventive concept. The mobile wireless phone 800 may be understood as a tablet PC. The semiconductor device in accordance with an embodiment of the inventive concept may be used to a portable computer such as a notebook PC, an MPEG audio layer-3 (MP3) player, an MP4 player, a navigation device, a solid state disk (SSD), a desktop computer, an automobile, and a household appliance, in addition to the tablet PC.

In accordance with an embodiment of the inventive concept, a stress pattern can be provided to face a source/drain region of a 3-dimensional transistor. The stress pattern can be formed of a material having a smaller residual stress value than silicon nitride. The stress pattern can enhance a performance of the transistor by improving resistance, effective mobility, and Ion characteristics of the transistor.

The foregoing is illustrative of embodiments and is not to be construed as limiting thereof. Although a few embodiments have been described, those skilled in the art will readily appreciate that many modifications are possible in embodiments without materially departing from the novel teachings and advantages. Accordingly, all such modifications are intended to be included within the scope of this inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A semiconductor device, comprising:
a semiconductor substrate having an active region;
a gate trench disposed to cross the active region;
first and second source/drain regions disposed in the active region at both sides of the gate trench;
a gate electrode disposed in the gate trench;
a gate dielectric layer disposed between the gate electrode and the active region; and
a stress pattern disposed on the gate electrode and in the gate trench, the stress pattern including a material having a lower residual stress than silicon nitride.

2. The semiconductor device of claim 1, wherein the material of the stress pattern has a lower permittivity than the silicon nitride.

3. The semiconductor device of claim 1, wherein the material of the stress pattern is a material of which residual stress and permittivity are lowered compared to those of silicon nitride by adding boron into the silicon nitride.

4. The semiconductor device of claim 1, wherein the material of the stress pattern is a material of which residual stress and permittivity are lowered compared to those of the silicon nitride by adding carbon or oxygen together with boron into the silicon nitride.

5. The semiconductor device of claim 1, further comprising an insulating pattern disposed on the gate electrode and in the gate trench,
wherein the insulating pattern includes a different material from the stress pattern.

6. The semiconductor device of claim 5, wherein the insulating pattern includes a material having a higher etch resistance than the stress pattern.

7. The semiconductor device of claim 5, wherein the insulating pattern is disposed on the stress pattern.

8. The semiconductor device of claim 5, wherein the stress pattern is interposed between the first and second source/drain regions and the insulating pattern.

9. The semiconductor device of claim 5, wherein the stress pattern covers side and bottom surfaces of the insulating pattern.

10. The semiconductor device of claim 1, wherein the active region has p-type conductivity, and the first and second source/drain regions have n-type conductivities.

11. The semiconductor device of claim 1, wherein the stress pattern faces the first and second source/drain regions and is spaced apart from the first and second source/drain regions.

12. The semiconductor device of claim 1, wherein the gate dielectric layer is interposed between the gate electrode and the active region, and between the stress pattern and the active region.

13. A semiconductor device, comprising:
a trench isolation layer disposed in a semiconductor substrate to define an active region;
a gate trench disposed to cross the active region and extend into the trench isolation layer;
a gate electrode disposed in the gate trench;
a stress pattern disposed in the gate trench and on the gate electrode, and formed of a material having a smaller residual stress value than silicon nitride;
a gate dielectric layer disposed between the gate electrode and the active region, and between the stress pattern and the active region; and
first and second source/drain regions disposed in the active region at both sides of the stress pattern.

14. The semiconductor device of claim 13, wherein the trench isolation layer includes a first isolation layer and a second isolation layer disposed on the first isolation layer, and
wherein the stress pattern has a smaller residual stress value than the second isolation layer.

15. The semiconductor device of claim 13, wherein the stress pattern is in direct contact with an upper surface of the gate electrode and faces the first and second source/drain regions.

16. A semiconductor device, comprising:
a semiconductor substrate having an active region;
a gate trench disposed to cross the active region;
first and second source/drain regions disposed in the active region at both sides of the gate trench;
a gate electrode disposed in the gate trench;
a gate dielectric layer disposed between the gate electrode and the active region; and
a stress pattern disposed on the gate electrode and in the gate trench,
wherein the stress pattern has a residual stress and permittivity that are lower than those of the silicon nitride.

17. The semiconductor device of claim 16, wherein the stress pattern is spaced apart from the active region.

18. The semiconductor device of claim 16, wherein the gate dielectric layer is interposed between the stress pattern and the first source/drain region, and between the stress pattern and the second source/drain region.

19. The semiconductor device of claim 16, wherein the stress pattern is formed of SiBN.

20. The semiconductor device of claim 16, wherein the stress pattern is formed of SiBCN.
